(19) United States
(12) Patent Application Publication
(10) Pub. No.: US 2016/0293251 A1
(43) Pub. Date: Oct. 6, 2016

(54) SEMICONDUCTOR MEMORY DEVICE

(71) Applicant: KABUSHIKI KAISHA TOSHIBA, Tokyo (JP)

(72) Inventors: Ryu OGIWARA, Yokohama Kanagawa (JP); Daisaburo TAKASHIMA, Yokohama Kanagawa (JP)

(73) Assignee: KABUSHIKI KAISHA TOSHIBA, Tokyo (JP)

(21) Appl. No.: 14/846,291

(22) Filed: Sep. 4, 2015

Related U.S. Application Data
(60) Provisional application No. 62/140,068, filed on Mar. 30, 2015.

(51) Int. Cl. G11C 13/00

(52) U.S. Cl. CPC G11C 13/004; G11C 2013/0054

(57) ABSTRACT

According to one embodiment, a semiconductor memory device includes: a plurality of memory cells, each of which including a memory element and a first switch element; the memory element storing data in accordance with a resistance values; a bit line connected to the memory cells; a charge transfer transistor that connects the bit line and a sense node; a sense circuit connected to the sense node; and a pulldown circuit connected to the bit line. The pulldown circuit causes a voltage of the bit line to drop to a first voltage obtained by subtracting a threshold voltage of the charge transfer transistor from a gate voltage of the charge transfer transistor before reading the data from the memory cell.

### CROSS-REFERENCE TO RELATED APPLICATIONS

This application claims the benefit of U.S. Provisional Application No. 62/140,068, filed Mar. 30, 2015, the entire contents of which are incorporated herein by reference.

### FIELD

Embodiments described herein relate generally to a semiconductor memory device.

### BACKGROUND

A charge transfer device is used in a semiconductor memory device.

### BRIEF DESCRIPTION OF THE DRAWINGS

FIG. 1 is a block diagram of a semiconductor memory device according to a first embodiment;

FIG. 2 is a plan view of a memory cell array included in the semiconductor memory device according to the first embodiment;

FIG. 3 is a circuit diagram of the memory cell array included in the semiconductor memory device according to the first embodiment;

FIG. 4 is a sectional view of a memory element included in the semiconductor memory device according to the first embodiment;

FIG. 5 is a plan view of the memory cell array included in the semiconductor memory device according to the first embodiment;

FIG. 6 is a circuit diagram of the memory cell array and a page buffer included in the semiconductor memory device according to the first embodiment;

FIG. 7 is a circuit diagram of the page buffer included in the semiconductor memory device according to the first embodiment;

FIG. 8 is a circuit diagram of a sequence controller included in the semiconductor memory device according to the first embodiment;

FIGS. 9, 10, and 11 are timing charts of a pulldown operation and a read operation of the semiconductor memory device according to the first embodiment;

FIG. 12 is a plan view of the memory cell array included in the semiconductor memory device according to a second embodiment;

FIG. 13 is a circuit diagram of the memory cell array included in the semiconductor memory device according to the second embodiment;

FIG. 14 is a circuit diagram of the memory cell array and the page buffer included in the semiconductor memory device according to the second embodiment;

FIG. 15 is a circuit diagram of the page buffer included in the semiconductor memory device according to the second embodiment;

FIG. 16 is a circuit diagram of the sequence controller included in the semiconductor memory device according to the second embodiment;

FIGS. 17 and 18 are circuit diagrams of the page buffer included in the semiconductor memory device according to a third embodiment;

FIG. 19 is a circuit diagram of the sequence controller included in the semiconductor memory device according to the third embodiment;

FIGS. 20 and 21 are timing charts of the pulldown operation and the read operation of the semiconductor memory device according to the third embodiment;

FIG. 22 is a circuit diagram of the page buffer included in the semiconductor memory device according to a fourth embodiment;

FIGS. 23 and 24 are timing charts of the pulldown operation and the read operation of the semiconductor memory device according to the fourth embodiment;

FIG. 25 is a circuit diagram of the page buffer included in the semiconductor memory device according to a fifth embodiment;

FIG. 26 is a circuit diagram of the sequence controller included in the semiconductor memory device according to the fifth embodiment; and

FIGS. 27 and 28 are timing charts of the pulldown operation and the read operation of the semiconductor memory device according to the fifth embodiment.

### DETAILED DESCRIPTION

In general, according to one embodiment, there is provided a semiconductor memory device comprising:

a plurality of memory cells, each of which including a memory element and a first switch element, the memory element storing data in accordance with a resistance value;

a bit line connected to the memory cells;

a charge transfer transistor that connects the bit line and a sense node;

a sense circuit connected to the sense node; and

a pulldown circuit connected to the bit line, wherein

the pulldown circuit causes a voltage of the bit line to drop to a first voltage obtained by subtracting a threshold voltage of the charge transfer transistor from a gate voltage of the charge transfer transistor before reading the data from the memory cell.

The embodiments will be described below with reference to the drawings. In the description that follows, the same reference numerals are attached to structural elements having substantially the same function and configuration, and a duplicate description will be provided only when necessary. The drawings are schematic. Each embodiment illustrates a device and a method to embody the technical idea of the embodiment, and the technical idea of the embodiment does not intend to limit the materials, shapes, structures, arrangements and the like of components to the following ones.

### First Embodiment

### [1] Configuration

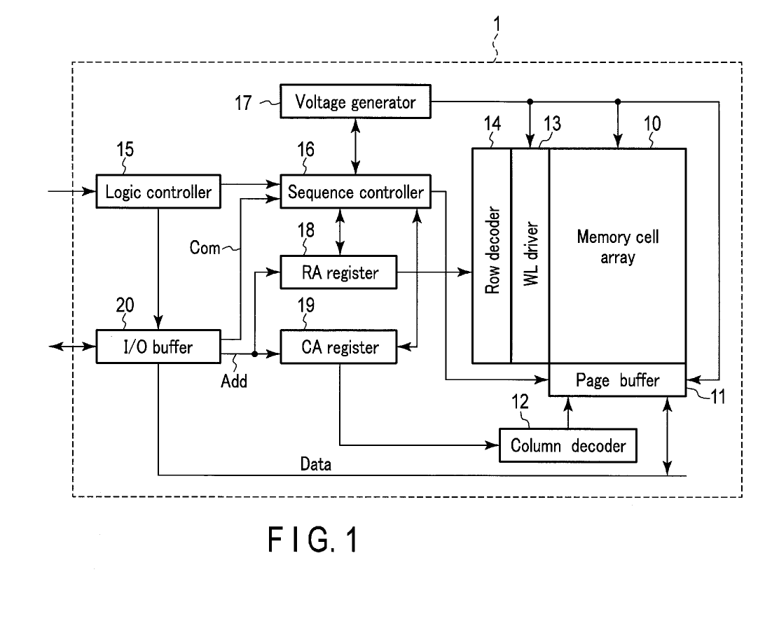

The basic configuration of a semiconductor memory device 1 will be described using FIG. 1. FIG. 1 is a block diagram of the semiconductor memory device 1 according to the first embodiment.

The semiconductor memory device 1 includes a memory cell array 10, a page buffer 11, a column decoder 12, a word line driver (WL driver) 13, a row decoder 14, a logic controller 15, a sequence controller (sequencer) 16, a voltage generator 17, a row address register (RA register) 18, a column address register (CA register) 19, and an input/output buffer (I/O buffer) 20.

The memory cell array 10 is a set of a plurality of nonvolatile memory cells MC, each associated with a source line and a bit line. As the memory cell MC, for example, a resistance change type memory cell such as an interfacial phase-change memory (iPCM) is used. Hereinafter, the semiconductor memory device 1 using iPCM as the memory cell MC is taken as an example in the description that follows.

An iPCM has two states, a high-resistance state and a low-resistance state, and a phase transition can be caused bidirectionally between the high-resistance state and the low-resistance state. Accordingly, an iPCM stores data “1” or “0”. The high-resistance state is set as “1” data and the low-resistance state is set as “0” data. However, the high-resistance state may be set as “0” data and the low-resistance state may be set as “1” data and the settings are not specifically limited.

Incidentally, as the memory cell MC, a resistance change type memory element such as resistance random access memory (ReRAM), phase-change RAM (PRAM), ferroelectric NAND-type memory (FeNAND), or magnetic random access memory (MRAM) may be used.

The column decoder 12 receives a column address signal from the CA register 19 to decode the column address signal. The decoded column address signal is set to the page buffer 11. The page buffer 11 selects the column in accordance with the column address signal.

When data is read, the page buffer 11 senses data read to a bit line from the memory cell MC and temporarily stores the read data. When data is written, the page buffer 11 temporarily stores write data sent from the input/output buffer 20 and transfers the write data to a bit line.

The row decoder 14 receives a row address signal from the RA register 18 to decode the row address signal. The decoded row address signal is sent to the word line driver 13. The word line driver 13 selects the row in accordance with the row address signal.

The word line driver 13 receives a row address signal from the row decoder 14 and applies appropriate voltages to a word line WL and a dummy word line DWL of the memory cell array 10.

The logic controller 15 receives control signals such as a chip enable signal, a command enable signal, an address latch enable signal, a write enable signal, and a read enable signal from outside. The logic controller 15 controls the operation of the input/output buffer 20 based on such control signals. Also, the logic controller 15 sends control signals to the sequencer 16.

The sequencer 16 controls the overall operation of the semiconductor memory device 1. The sequencer 16 executes sequence control of writing, reading, or erasing of data in accordance with a command Com received from the input/output buffer 20.

The voltage generator 17 generates a voltage needed for writing or reading data and supplies the voltage to the memory cell array 10, the page buffer 11, and the word line driver 13. The voltage generator 17 contains a voltage boosting circuit, a voltage lowering circuit, and a band-gap reference (BGR) circuit (no circuit is shown). The voltage boosting circuit generates a voltage higher than an external power supply VDD by a charge pump circuit. The voltage lowering circuit generates a voltage lower than the external power supply VDD by a PMOS feedback circuit. The BGR circuit generates a constant voltage that is independent of the temperature and the external power supply VDD. The voltage generated by the BGR circuit is used as a reference voltage.

The RA register 18 receives and holds a row address signal via the input/output buffer 20. The row address signal held in the RA register 18 is sent to the row decoder 14.

The CA register 19 receives and holds a column address signal via the input/output buffer 20. The column address signal held in the CA register 19 is sent to the column decoder 12.

The input/output buffer 20 receives an address signal Add, a command Com. and data from outside. The command Com is sent to the sequencer 16. The address signal Add contains a column address signal and a row address signal. The column address signal is sent to the CA register 19 and the row address signal is sent to the RA register 18. When data is written, the input/output buffer 20 sends write data received from outside to the page buffer 11. When data is read, the input/output buffer 20 outputs read data received from the page buffer 11 to the outside.

[1-1] Memory Cell Array 10

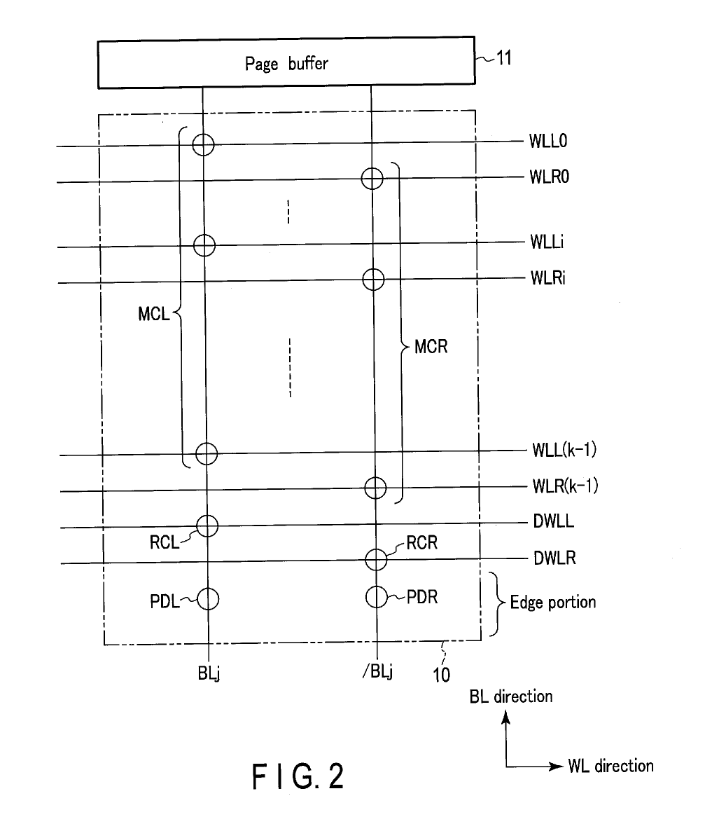

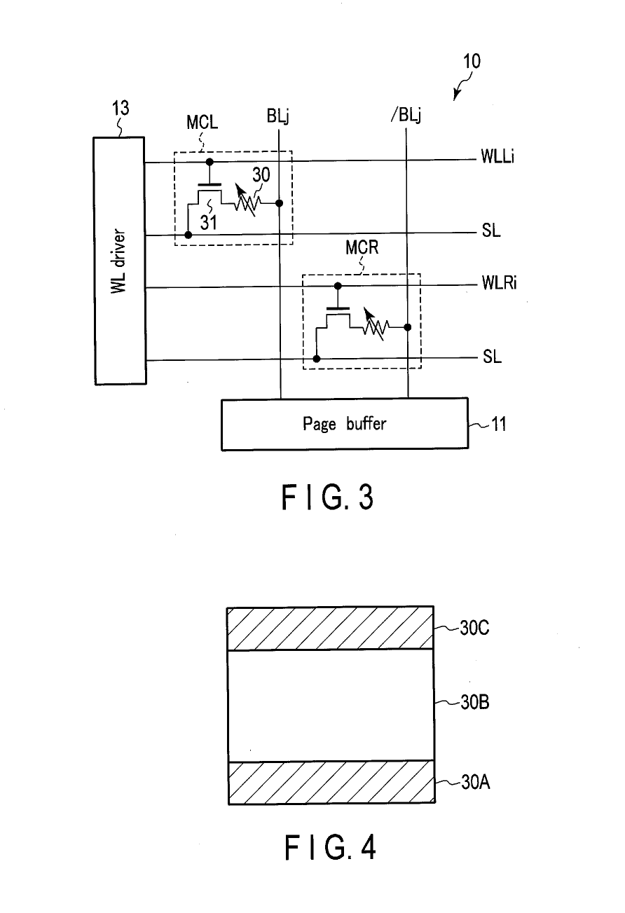

The configuration of the memory cell array 10 will be described using FIGS. 2 and 3. FIG. 2 is a plan view of the memory cell array 10 included in the semiconductor memory device 1 according to the first embodiment. FIG. 3 is a circuit diagram of the memory cell array 10 included in the semiconductor memory device 1 according to the first embodiment.

The memory cell array 10 includes a plurality of bit lines, a plurality of word lines, and a plurality of memory cells.

The plurality of bit lines are arranged in a WL direction and contain m (m is a natural number equal to 1 or greater) bit line pairs (bit lines BL, /BL). FIG. 2 shows one bit line pair (bit lines BLj, /BLj (j is an integer equal to 0 or greater)).

The plurality of word lines are arranged in a BL direction and contain k (k is a natural number equal to 1 or greater) word line pairs (word lines WLL, WLR). The i-th (i is an integer equal to 0 or greater) word lines WLL, WLR will be denoted as word lines WLLi, WLRi.

Memory cells are arranged, for example, in a staggered configuration. The memory cell to which the bit line BLj and the word line WLLi are connected will be denoted as the memory cell MCL and the memory cell to which the bit line /BLj and the word line WLRi are connected will be denoted as the memory cell MCR. The memory cells MCL, MCR are configured similarly, and are denoted simply as memory cells MC in the description that follows.

The circuit configuration of the memory cell array 10 will be described using FIG. 3.

The memory cell array 10 includes a plurality of source lines. Source lines SL are arranged in the BL direction and as many source lines as the number of, for example, word lines are provided. Each source line SL is arranged between, for example, word lines.

The memory cell MC includes a memory element 30 and a select transistor 31. The memory element 30 is configured to the iPCM. One end of the memory element 30 is connected to the bit line and the other end is connected to one end of the select transistor 31. The select transistor 31 is an n-channel MOS transistor (NMOS transistor), with one end thereof connected to the source line SL and the gate thereof connected to the word line.

The bit lines BLj, /BLj are connected to the page buffer 11. One column of the memory cell array 10 is connected to one bit line.

The word lines WLLi, WLRi are connected to the word line driver 13. One row of the memory cell array 10 is connected to a pair including one word line and one source line SL.

With the above configuration, when data is read from or written to the memory cell MC, the page buffer 11 can pass a current to the memory cell MC selected by the word line and the bit line.

Incidentally, the order of connection of the memory element 30 and the select transistor 31 may be reversed. In such a case, one end of the memory element 30 is connected to the source line SL and the other end is connected to one end of the select transistor 31. The other end of the select transistor 31 is connected to the bit line and the gate thereof is connected to the word line.

An example of the configuration of the memory element 30 in iPCM will be described using FIG. 4. FIG. 4 is a sectional view of the memory element 30 included in the semiconductor memory device 1 according to the first embodiment.

The memory element 30 includes a lower electrode 30A, a memory layer 30B, and an upper electrode 30C.

The lower electrode 30A and the upper electrode 30C are provided across the memory layer 30B and are used for connection to a circuit. The memory layer 30B is a superlattice including, for example, germanium atoms Ge, tellurium atoms Te, and antimony atoms Sb and in which a germanium tellurium layer and an antimony-tellurium layer are stacked. The superlattice changes to a high-resistance state or a low-resistance state after the crystalline state changes. More specifically, if, for example, a necessary voltage pulse is applied to a superlattice, germanium atoms Ge in the sueprlattice move, thereby changing the bonded state of germanium atoms Ge and tellurium atoms Te. In an iPCM, for example, the low-resistance state is called the set state and the high-resistance state is called the reset state.

Returning to FIG. 2, the memory cell array 10 comprises a dummy word line pair, a plurality of reference cells RCL, RCR, and a plurality of pulldown circuits PDL, PDR.

The dummy word line pair (dummy word lines DWLL, DWLR) is contained in a plurality of word lines. The dummy word line pair is provided in accordance with the number of reference cells RCL, RCR connected to one bit line. The dummy word line pair is arranged such that, for example, the plurality of word lines are sandwiched between the dummy word line pair and the page buffer 11.

One or more reference cells RCL, RCR are provided on the bit lines BLj, /BLj respectively and arranged in a staggered configuration together with the memory cells MCL, MCR. One end of the reference cell RCL is connected to the dummy word line DWLL and the other end thereof is connected to the bit line BLj. One end of the reference cell RCR is connected to the dummy word line DWLR and the other end thereof is connected to the bit line /BLj.

The pulldown circuits PDL, PDR have a function to pull down charges of a bit line and provided in accordance with the number of bit lines. The pulldown circuit PDL is connected to the bit line BLj and the pulldown circuit PDR is connected to the bit line /BLj. The pulldown circuits PDL, PDR are arranged such that a plurality of memory cells and a plurality of reference cells are sandwiched between the pulldown circuits and the page buffer 11. That is, the pulldown circuits PDL, PDR are arranged at an end portion of the memory cell array 10. The pulldown circuits PDL, PDR are simplified as pulldown circuit PD in the description below.

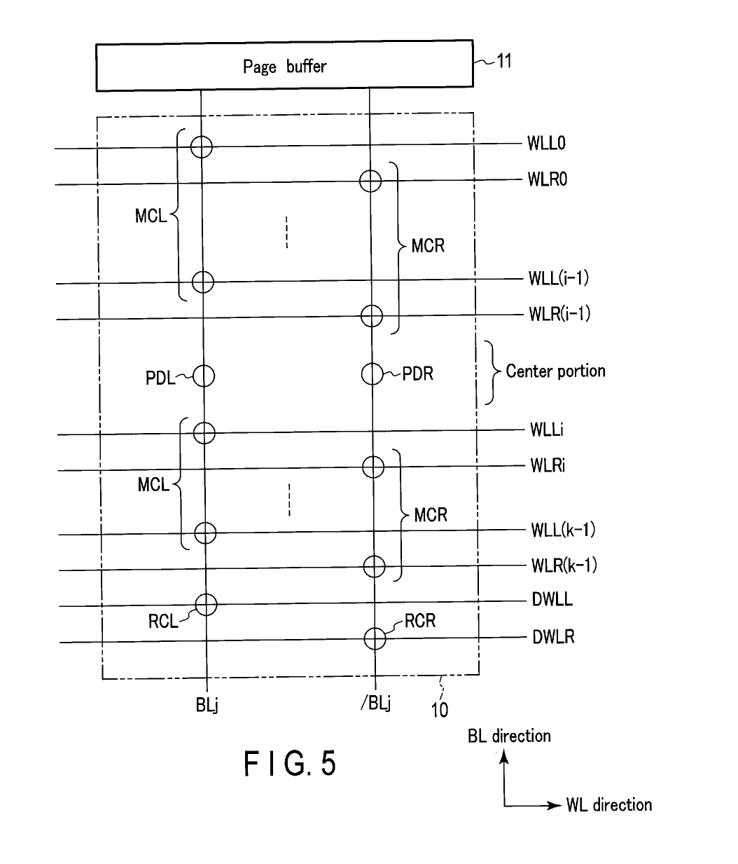

The pulldown circuits PDL, PDR may be arranged, as shown in FIG. 5, in the center portion of the memory cell array 10. More specifically, the pulldown circuits PDL, PDR are arranged between the word lines WLLi, WLRi and the word lines WLL(i-1), WLR(i-1). Thus, the pulldown circuits PDL, PDR may be arranged between word lines to be arrayed and are not specifically limited.

When data of the memory cell MCL is read by the bit line pair BLj, /BLj, the reference cell RCR is used. On the other hand, when data of the memory cell MCR is read by the bit line pair BLj, /BLj, the reference cell RCL is used. Thus, when data of the memory cell MC connected to one bit line of the bit line pair BLj, /BLj is read, the reference cell connected to the other bit line is used.

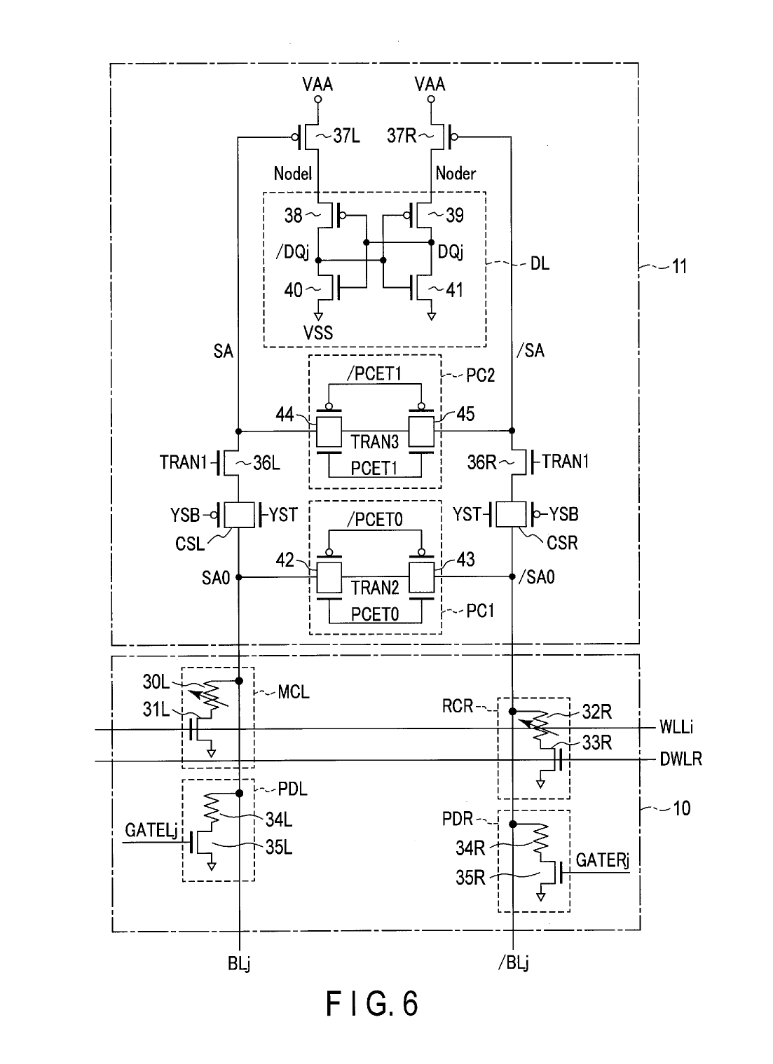

The circuit configuration of the reference cell and the pulldown circuit PD will be described using FIG. 6. FIG. 6 is a circuit diagram of the memory cell array 10 and the page buffer 11 included in the semiconductor memory device according to the first embodiment and shows one bit line pair BLj, /BLj and the page buffer 11 corresponding thereto. FIG. 6 also shows one memory cell MCL and one reference cell RCR to illustrate a read operation of data stored in the memory cell MCL to which the word line WLLi is connected. Details of the circuit configuration and operation of the page buffer 11 will be described later.

The reference cell RCR comprises a reference resistance element 32R (32) and a select transistor 33R (33). The reference resistance element 32 is used when data is read and the resistance value of the reference resistance element 32 is set to an intermediate level between the high-resistance state and the low-resistance state of the memory element 30. One end of the reference resistance element 32R is connected to the bit line /BLj and the other end thereof is connected to one end of the select transistor 33R. The select transistor 33R is an re-channel MOS transistor, and a ground voltage (for example, 0 V) is applied to the other end thereof and the gate thereof is connected to the dummy word line DWLR. That the ground voltage is applied means that a grounding terminal is connected.

On the other hand, the reference cell RCL (not shown) comprises a reference resistance element 32L (32) and a select transistor 33L (33). One end of the reference resistance element 32L is connected to the bit line BLj and the gate of the select transistor 33L is connected to the dummy word line DWLL. The remaining configuration of the reference cell RCL is the same as that of the reference cell RCR.

Incidentally, the order of connection of the reference resistance element 32 and the select transistor 33 may be reversed. In such a case, the ground voltage is applied to one end of the reference resistance element 32 and the other end thereof is connected to one end of the select transistor 33. The other end of the select transistor 33 is connected to the bit line.

The pulldown circuit PDL comprises a pulldown resistance element 34L (34) and a transistor 35L (35). The pulldown resistance element 34 is used to precharge the voltage of the bit line to the gate voltage of the charge transfer transistor minus threshold voltage of the charge transfer transistor in a short time, and the resistance value of the pulldown resistance element 34 is, for example, approximately the same as that of the reference resistance element 32. One end of the pulldown resistance element 34L is connected to the bit line BLj and the other end thereof is connected to one end of the transistor 35L. The transistor 35L (35) is an n-channel MOS transistor. The ground voltage is applied to the other end of the transistor 35L and a control signal GATELj is input into the gate thereof.

On the other hand, the pulldown circuit PDR (not shown) comprises a pulldown resistance element 34R (34) and a transistor 35R (35). One end of the pulldown resistance element 34R is connected to the bit line /BLj and a control signal GATERj is input into the gate of the transistor 35R. The remaining configuration of the pulldown circuit PDR is the same as that of the pulldown circuit PDL.

Incidentally, the order of connection of the pulldown resistance element 34 and the transistor 35 may be reversed. In such a case, the ground voltage is applied to one end of the pulldown resistance element 34 and the other end thereof is connected to one end of the transistor 35. The other end of the transistor 35 is connected to the bit line BL.

[1-2] Page Buffer 11

The circuit configuration of the page buffer 11 will be described using FIG. 6. FIG. 6 is a circuit diagram of a memory cell array and a page buffer.

The page buffer 11 includes a column switch CS, a charge transfer transistor 36, a transistor 37, precharge circuits PC1, PC2, and a data holding circuit DL.

The column switch CS is provided for each bit line pair to electrically connect the bit line pair intended for reading or writing and the page buffer 11. The column switches CS corresponding to the bit lines BLj, /BLj will be denoted as column switches CSL, CSR respectively.

The column switch CS is configured by, for example, a transfer gate. The transfer gate is connected in parallel and includes an n-channel MOS transistor and a p-channel MOS transistor (PMOS transistor) into which column selection signals YST, TYB are input respectively in the gate. One end of the column switch CSL is connected to a bit line node SA0 and the other end thereof is connected to one end of a transistor 36L. One end of the column switch CSR is connected to a bit line node /SA0 and the other end thereof is connected to one end of a transistor 36R.

The charge transfer transistor 36 is configured by, for example, an n-channel MOS transistor and separates sense nodes SA, /SA of the page buffer 11 of a small capacity and the bit line nodes SA0, /SA0 on the bit line side with a large capacity. The charge transfer transistors 36 corresponding to the bit lines BLj, /BLj will be denoted as the transistors 36L, 36R respectively.

The other end of the transistor 36L is connected to the sense node SA and a voltage TRAN1 is applied to the gate thereof. The other end of the transistor 36R is connected to the sense node /SA and the voltage TRAN1 is applied to the gate thereof. The voltage TRAN1 is, for example, 1.4 V and is set higher than a threshold voltage Vth (for example, 1.0 V) of the charge transfer transistor 36.

The transistor 37 is a p-channel MOS transistor and detects voltage fluctuations of the sense nodes SA, /SA of the page buffer 11 and forms a current path between the data holding circuit DL and a power supply voltage VAA (for example, 1.8 V). The transistors 37 corresponding to the sense nodes SA, /SA will be denoted as transistors 37L, 37R.

The power supply voltage VAA is applied to one end of the transistor 37L, the other end thereof is connected to a node Nodel, and the gate thereof is connected to the sense node SA. The power supply voltage VAA is applied to one end of the transistor 37R, the other end thereof is connected to a node Noder, and the gate thereof is connected to the sense node /SA.

The precharge circuit PC1 includes switch elements 42, 43 to precharge the bit line nodes SA0, /SA0.

The switch element 42 is configured by, for example, a pair of n-channel MOS transistor and p-channel MOS transistor. The n-channel MOS transistor and p-channel MOS transistor are connected in parallel. Control signals PCET0, /PCET0 are input to the gate of the n-channel MOS transistor and the gate of the p-channel MOS transistor, respectively. One end of the switch element 42 is connected to the bit line node SA0 and a voltage TRAN2 is applied to the other end thereof. The voltage TRAN2 is, for example, 0.5 V and is set higher than a difference between the voltage TRAN1 and the threshold voltage of the charge transfer transistor 36.

The switch element 43 is configured in the same manner as the switch element 42 and one end thereof is connected to the bit line node /SA0 and the voltage TRAN2 is applied to the other end.

The precharge circuit PC2 includes switch elements 44, 45 to precharge the sense nodes SA, /SA.

The switch element 44 is configured by, for example, a pair of n-channel MOS transistor and p-channel MOS transistor. The n-channel MOS transistor and p-channel MOS transistor are connected in parallel. Control signals PCET1, /PCET1 are input to the gate of the n-channel MOS transistor and the gate of the p-channel MOS transistor, respectively. One end of the switch element 44 is connected to the sense node SA and a voltage TRAN3 is applied to the other end thereof. The voltage TRAN3 is, for example, the power supply voltage VAA (for example, 1.8 V) and is set to a value that does not turn on the transistors 37L, 37R.

The switch element 45 is configured in the same manner as the switch element 44 and one end thereof is connected to the sense node /SA and the voltage TRAN3 is applied to the other end.

The data holding circuit DL holds data read from bit lines. The data holding circuit DL is configured by, for example, two inverter circuits in which mutual inputs are connected to mutual outputs (cross-coupled). The data holding circuit DL includes p-channel MOS transistors 38, 39 and n-channel MOS transistors 40, 41.

One end of the transistor 38 is connected to the node Nodel, the other end thereof is connected to a node /DQj, and the gate thereof is connected to a node DQj. One end of the transistor 39 is connected to the node Noder, the other end thereof is connected to the node DQj, and the gate thereof is connected to the node /DQj.

One end of the transistor 40 is connected to the node /DQj, the ground voltage is applied to the other end thereof, and the gate thereof is connected to the node DQj. One end of the transistor 41 is connected to the node DQj, the ground voltage is applied to the other end thereof, and the gate thereof is connected to the node /DQj.

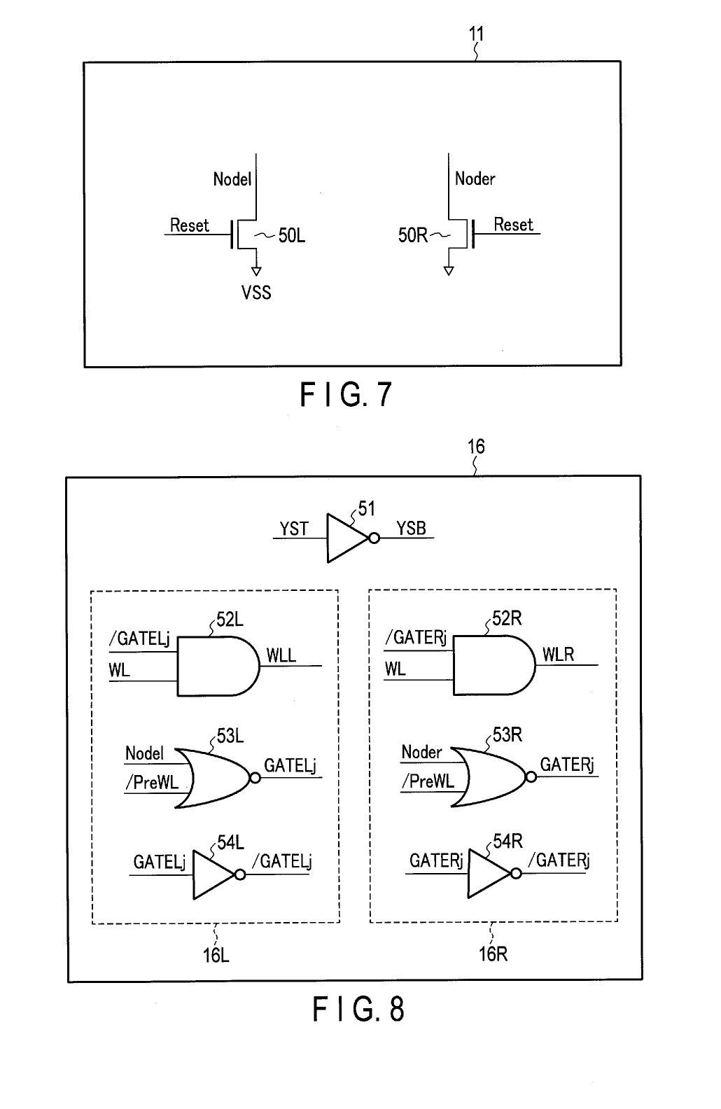

Another circuit configuration of the page buffer 11 will be described using FIG. 7.

The page buffer 11 includes a transistor 50. The transistor 50 is an n-channel MOS transistor and is used for a reset operation of a node connecting the transistor 37 and the data holding circuit DL. The transistors 50 corresponding to the sense nodes Nodel, Noder will be denoted as transistors 50L, 50R respectively.

One end of the transistor 50L is connected to the node Nodel, the ground voltage is applied to the other end thereof, and a control signal Reset is input into the gate thereof. One end of the transistor 50R is connected to the node Noder, the ground voltage is applied to the other end thereof, and the control signal Reset is input into the gate thereof.

The logic circuit configuration of the sequencer 16 related to the operation of the page buffer 11 will be described using FIG. 8. FIG. 8 is a circuit diagram of the sequencer 16 included in the semiconductor memory device 1 according to the first embodiment. The sequencer 16 includes an inverter circuit 51 and control circuits 16L, 16R.

The inverter circuit 51 is used to control the column switch CS and inverts the column selection signal YST and outputs a column selection signal YSB.

The control circuit 16L includes an AND gate 52L, a NOR gate 53L, and an inverter circuit 54L and is used for the operation on the sense node SA side in the page buffer 11. The control circuit 16R includes an AND gate 52R, a NOR gate 53R, and an inverter circuit 54R and is used for the operation on the sense node /SA side in the page buffer 11.

The AND gate 52L performs an AND operation of a control signal /GATELj and a control signal WL and outputs a control signal WLL. The AND gate 52R performs an AND operation of a control signal /GATERj and the control signal WL and outputs a control signal WLR.

When data of the memory cell MCL to which the word line WLLi is connected is read, the control signal WLL is input into the word line WLLi. At this point, an “H” level signal is input into the word line DWLR.

On the other hand, when data of the memory cell MCR to which the word line WLRi is connected is read, the control signal WLR is input into the word line WLRi and at this point, an “H” level signal is input into the word line DWLL.

The NOR gate 53L performs a NOT-OR operation of the voltage of the node Nodel and a control signal /PreWL and outputs the control signal GATELj. The NOR gate 53R performs a NOT-OR operation of the voltage of the node Noder and the control signal /PreWL and outputs the control signal GATERj. The control signal /PreWL controls a pulldown operation described later.

The inverter circuit 54L inverts the control signal GATELj and outputs the control signal /GATELj. The inverter circuit 54R inverts the control signal GATERj and outputs the control signal /GATERj.

[2] Operation

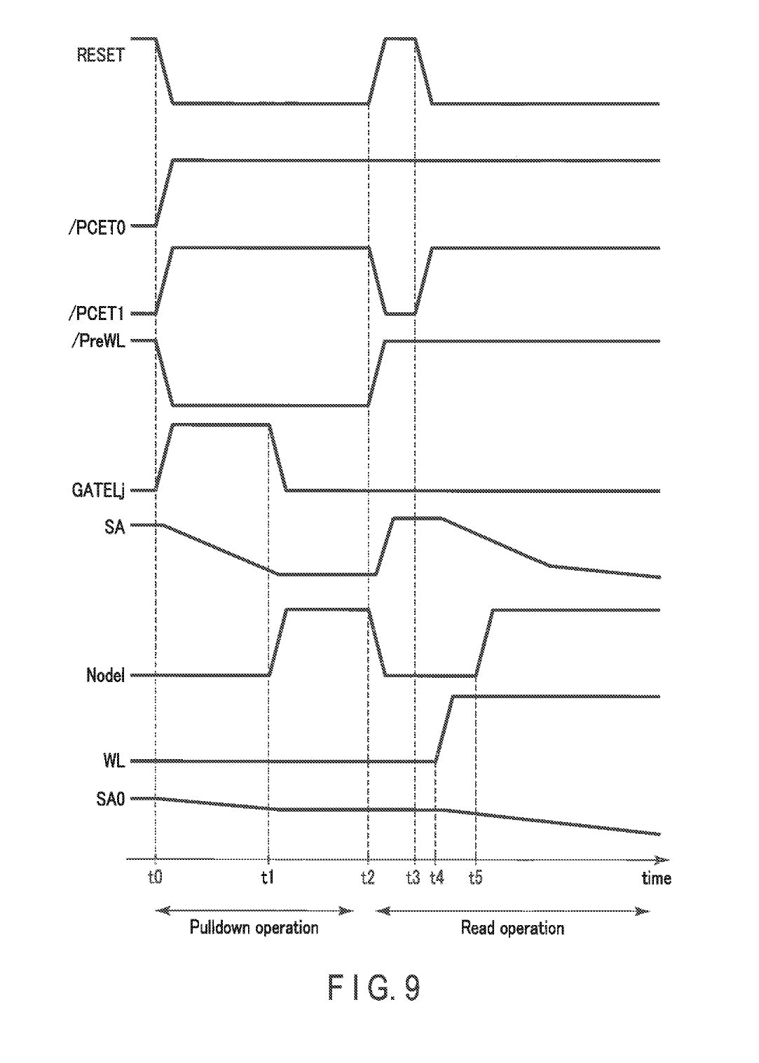

The pulldown operation and the read operation of the semiconductor memory device 1 will be described using FIGS. 9 to 11. FIGS. 9 to 11 are timing charts of the pulldown operation and the read operation of the semiconductor memory device 1 according to the first embodiment. When an element on the sense node SA side and an element on the sense node /SA side perform the same operation in the page buffer 11, the description of the element on the sense node /SA side is omitted.

Before a read operation of data is performed, first a reset operation is performed. More specifically, the control signal Reset is set to the “H” level and the control signals /PCET0, /PCET1 are set to the “L” level. The “L” level is a voltage at which an n-channel MOS transistor into which a control signal is input is turned off and a p-channel MOS transistor into which a control signal is input is turned on. If the control signal Reset is set to the “H” level, the transistors 50L, 50R are turned on. Accordingly, the ground voltage is applied to the nodes Nodel, Noder and the nodes Nodel, Noder change to the “L” level (approximately 0 V).

If the control signal /PCET0 is set to the “L” level, the switch elements 42, 43 are turned on. Accordingly, the bit line nodes SA0, /SA0 are precharged to the voltage TRAN2 (for example, 0.5 V). If the control signal /PCET1 is set to the “L” level, the switch elements 44, 45 are turned on. Accordingly, the sense nodes SA, /SA are precharged to the voltage TRAN3 (for example, 1.8 V).

Next, the pulldown operation is performed. The pulldown operation lowers the voltage of the bit line nodes SA0, /SA0 and makes the memory cell array 10 and the page buffer 11 ready for reading after the pulldown operation. The operation of the memory cell array 10 and the page buffer 11 during pulldown operation and read operation will be described using FIG. 9.

First, the control signal Reset is set to the “L” level, the control signals /PCET0, /PCET1 are set to the “H” level, and the control signal /PreWL is set to the “L” level (time t0).

If the control signal Reset is set to the “L” level, the transistor 50L turned off.

If the control signal /PCET0 is set to the “H” level, the switch elements 42, 43 are turned off. Accordingly, the precharge of the bit line nodes SA0, /SA0 by the precharge circuit PC1 is canceled.

If the control signal /PCET1 is set to the “H” level, the switch elements 44, 45 are turned off. Accordingly, the precharge of the sense nodes SA, /SA by the precharge circuit PC2 is canceled.

If the control signal /PreWL is set to the “L” level, the control signal GATELj changes to the “H” level to start the pulldown operation. More specifically, the node Nodel and the control signal /PreWL change to the “L” level and thus, the NOR gate 53L sets the control signal GATELj to the “H” level. Accordingly, the transistor 35L of the pulldown circuit PDL is turned on and the voltage of the bit line node SA0 starts to drop.

At this point, the voltage TRAN1 (for example, 1.4 V) applied to the gate of the transistor 36L is smaller than the sum of the threshold voltage Vth (for example, 1.0 V) of the transistor 36L and the voltage (for example, 0.5 V) of the bit line node SA0 and thus, a charge is transferred from the sense node SA to the bit line node SA0 and the voltage of the sense node SA starts to drop.

When the voltage of the sense node SA drops to the “L” level, the transistor 37L is turned on (time t1).

When the transistor 37L is turned on, the power supply voltage VAA is applied to the node Nodel so that the node Nodel changes to the “H” level. When the node Nodel is at the “H” level, the NOR gate 53L sets the control signal GATELj to the “L” level. At this point, the voltage of the bit line node SA0 is approximately the same as (the voltage TRAN1−the threshold voltage Vth). The reason is that a transistor which transfers charge supplied from the sense node SA turns on only in a case of V(TRAN1)−Vth≧V(SA0).

Next, the control signal /PCET1 is set to the “L” level and then, the control signal Reset is set to the “H” level and the control signal /PreWL is set to the “H” level (time t2).

If the control signal Reset is set to the “H” level, the ground voltage is applied to the node Nodel and the voltage of the node Nodel changes to the “L” level (approximately 0 V). If the control signal /PCET1 is set to the “L” level, the sense nodes SA, /SA are precharged to the voltage TRANS. If the control signal /PreWL is set to the “H” level, the NOR gate 53L sets the control signal GATELj to the “L” level to terminate the pulldown operation.

Next, the control signal Reset is set to the “L” level and the control signal /PCET1 is set to the “H” level (time t3). Accordingly, the ground voltage is no longer applied to the node Nodel and the precharge of the sense nodes SA, /SA ends.

Next, the control signal WL is set to the “H” level to start a read operation (time t4).

If the control signal WL is set to the “H” level, the control signal /GATELj is already at the “H” level and the control signal WL changes to the “H” level and thus, the AND gate 52L sets the control signal WLL to the “H” level. Accordingly, the control signal WLL is input into the word line WLLi. At this point, an “H” level signal is input into the word line DWLR.

If the word line WLLi changes to the “H” level, the select transistor 31L is turned on and the voltage of the bit line node SA0 starts to drop. Correspondingly, the charge transfer transistor 36L transfers a charge from the sense node SA to the bit line node SA0 and the voltage of the sense node SA drops. The speed at which the voltage drops is different in the sense nodes SA, /SA.

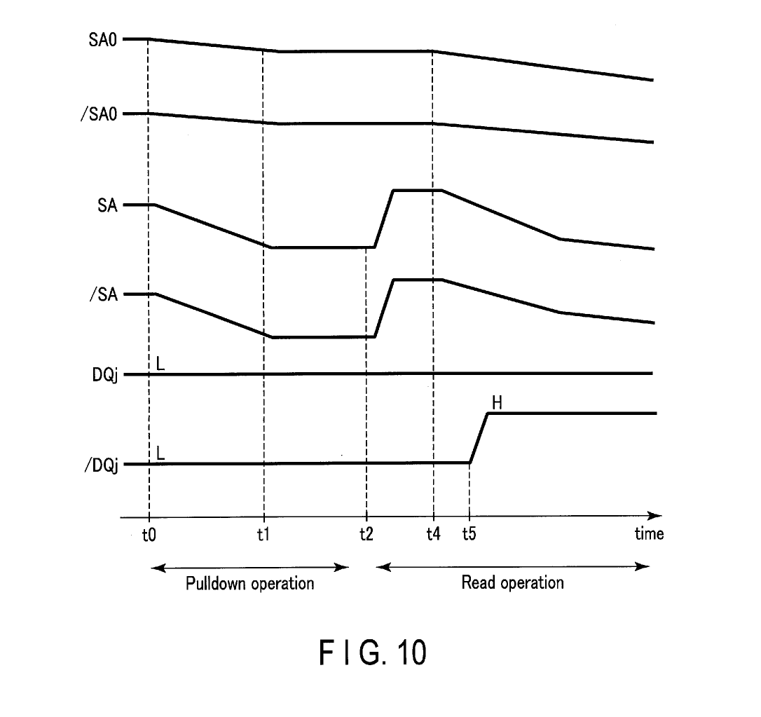

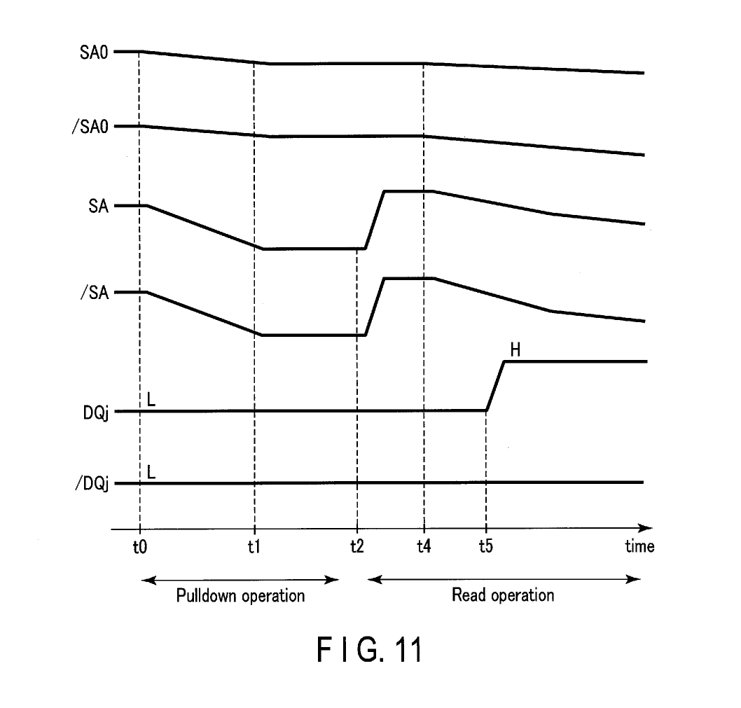

Next, the operation of the page buffer 11 after time t4 in FIG. 9 will be described using FIGS. 10 and 11. FIG. 10 is a timing chart when data of the memory cell MC to be read is “0” and FIG. 11 is a timing chart when data of the memory cell MC to be read is “1”. The times in FIGS. 10 and 11 correspond to the times in FIG. 9.

If, as shown in FIG. 10, data of the memory cell MC to be read is “0”, the voltage of the sense node SA first drops and the transistor 37L is first turned on. Accordingly, the power supply voltage VAA is applied to the node Nodel and the voltage of the node /DQj changes to the “H” level (time t5). Then, the transistor 39 is turned off and the transistor 41 is turned on and the node DQi changes to the “L” level. Accordingly, “0” data is held in the data holding circuit DL.

On the other hand, if, as shown in FIG. 11, data of the memory cell MC to be read is “1”, the voltage of the sense node /SA first drops and the transistor 37R is first turned on. Accordingly, the power supply voltage VAA is applied to the node Noder and the voltage of the node DQj changes to the “H” level (time t5). Then, the transistor 38 is turned off and the transistor 40 is turned on. Accordingly, “1” data is held in the data holding circuit DL.

The speed of the voltage drop of the sense nodes SA, /SA is slower by way of a reference cell than by way of the memory cell MC (low-resistance state) in which “0” data is held and still slower by way of the memory cell MC (high-resistance state) in which “1” data is held than by way of the reference cell. That is, time t5 at which the transistor 37L is turned on when “0” data is read is earlier than time t5 at which the transistor 37R is turned on when “1” data is read.

Thus, data of the memory cell MCL connected to the bit line BLj can be read in the manner described above. When data of the memory cell MCR connected to the bit line /BLj is read, the operation corresponding to the bit line BLj and the operation corresponding to the bit line /BLj in the above case when data of the memory cell MCL is read may be reversed.

In the pulldown circuit PD, the resistance value of the pulldown resistance element 34 poses a problem. If the resistance value of the pulldown resistance element 34 is too small, the voltage of the bit line nodes SA0, /SA0 can be caused to drop in a shorter time, but the voltage of the bit line nodes SA0, /SA0 may be caused to drop too far and there is the possibility that the voltage of the bit line nodes SA0, /SA0 is caused to drop below the TRAN1 voltage−threshold voltage.

If, on the other hand, the resistance value of the pulldown resistance element 34 is too large, the voltage of the bit line nodes SA0, /SA0 can be just adjusted to the TRAN1 voltage−threshold voltage, but it may take too much time.

Thus, the speed at which the pulldown circuit PD causes the voltage to drop and the speed at which a memory cell causes the voltage to drop is desirably such an extent to which time constants are matched. More specifically, the resistance value of the pulldown resistance element 34 is desirably equal to the resistance value of the memory element 30 in a low-resistance state or more and equal to the resistance value of the memory element 30 in a high-resistance state or less and generally set to the resistance value or so of a reference cell.

[3] Effect of the First Embodiment

In a resistance change type semiconductor memory device, a technology of sensing using a charge transfer device (charge transfer transistor) is widely known. The charge transfer transistor is configured by an n-channel MOS transistor, separates a bit line with a large capacity and a sense node with a small capacity, and transfers a micro-charge on the bit line side to the sense node side. Accordingly, voltage changes of the sense node increase, making sensing easier.

If such a configuration is adopted, however, a problem of a longer time to precharge the voltage on the bit line side to (the gate voltage of the charge transfer transistor−threshold voltage of the charge transfer transistor) is posed.

Thus, in the semiconductor memory device 1 according to the first embodiment, the time of precharge is reduced by causing the voltage on the bit line side to drop by a pulldown operation before a read operation. More specifically, the pulldown circuit PD is provided for each bit line. The pulldown circuit PD is turned on before a read operation to cause the voltage of the bit line nodes SA0, /SA0 to drop. When the voltage of the bit line nodes SA0, /SA0 drops to (the gate voltage of the charge transfer transistor 36−threshold voltage of the charge transfer transistor 36), the pulldown circuit PD is turned off to enable a read operation. Accordingly, the time to precharge the bit line nodes SA0, /SA0 before reading can be reduced. With the above configuration, the semiconductor memory device 1 can make the operation faster.

In addition, the semiconductor memory device 1 according to the first embodiment includes the p-channel MOS transistor 37 in which the sense node SA is connected to the gate and read data is transferred to the data holding circuit DL by the operation of the transistor 37. Accordingly, the data holding circuit DL can automatically hold read data without the timing being provided from outside. With the above configuration, the semiconductor memory device 1 can reduce the probability of erroneously reading data.

### Second Embodiment

A semiconductor memory device 1 according to the second embodiment uses a diode for the selection of a memory cell MC and the operation of a pulldown circuit PD.

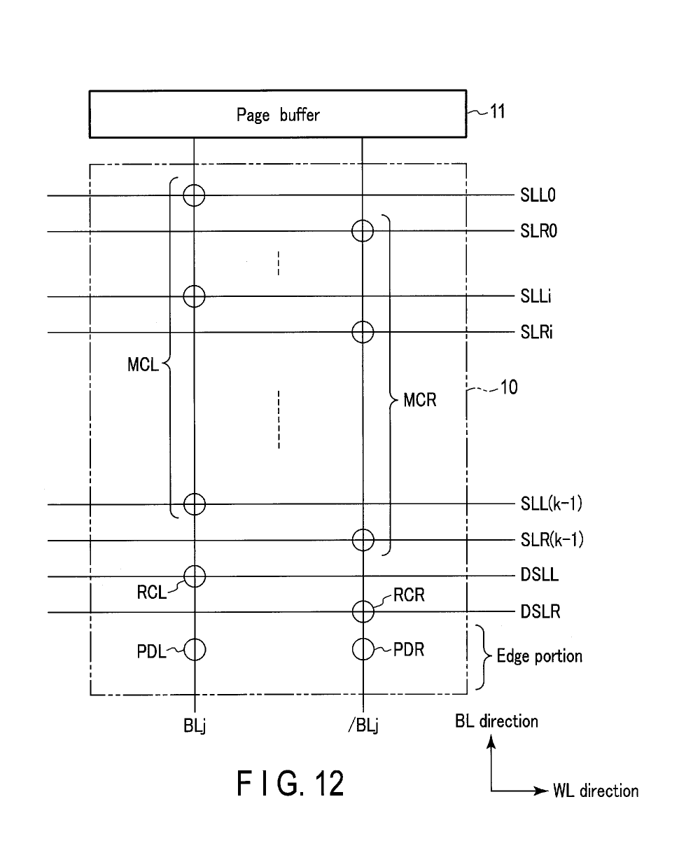

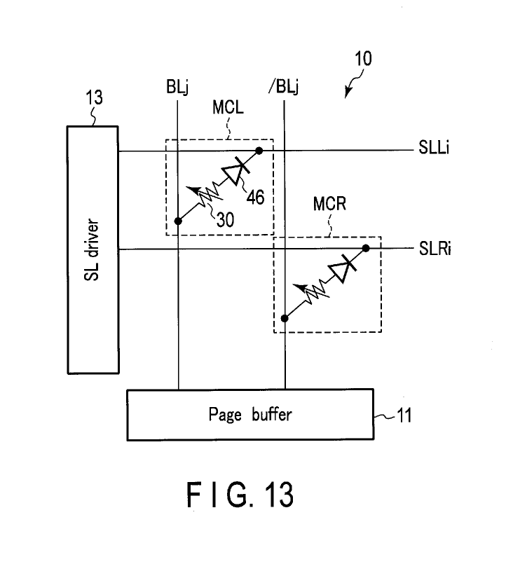

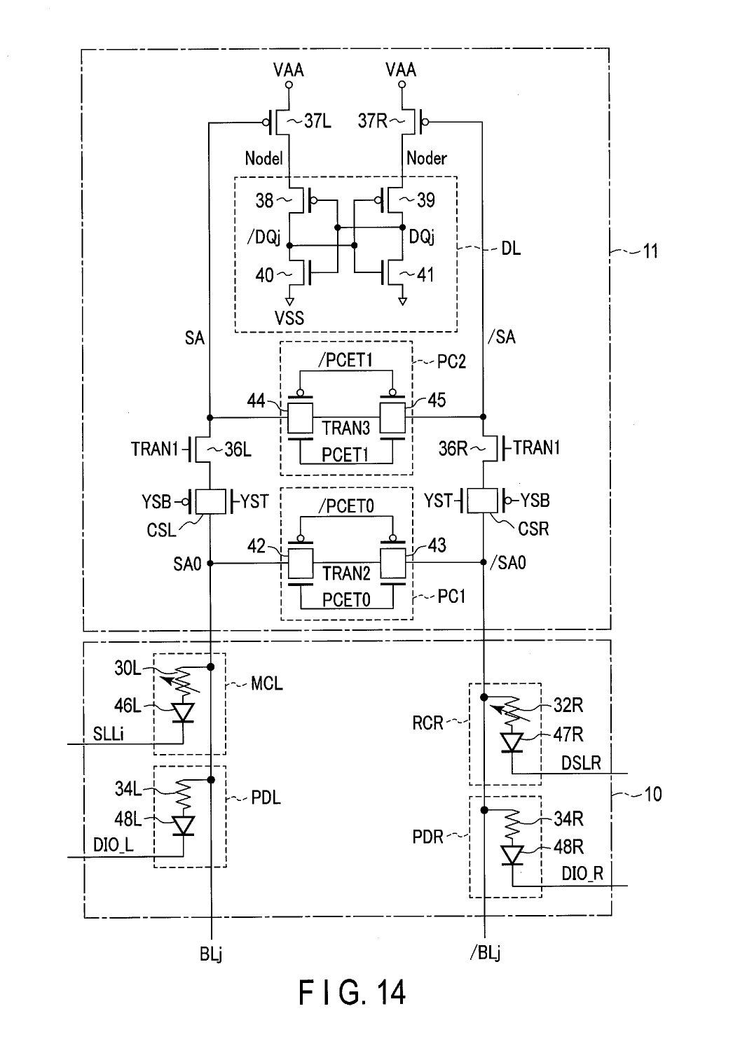

The configuration of a memory cell array 10 will be described using FIGS. 12 and 13. FIG. 12 is a plan view of the memory cell array 10 included in the semiconductor memory device 1 according to the second embodiment. FIG. 13 is a circuit diagram of the memory cell array 10 included in the semiconductor memory device 1 according to the second embodiment.

The memory cell array 10 includes a plurality of bit lines, a plurality of source lines, and a plurality of memory cells.

The plurality of bit lines are arranged in a source line direction and contain m (m is a natural number equal to 1 or greater) bit line pairs (bit lines BL, /BL). FIG. 12 shows one bit line pair (bit lines BLj, /BLj (j is an integer equal to 0 or greater)).

The plurality of source lines are arranged in a BL direction and contain k (k is a natural number equal to 1 or greater) source line pairs (source lines SLL, SLR). The i-th (i is an integer equal to 0 or greater) source lines SLL, SLR will be denoted as source lines SLLi, SLRi.

A plurality of memory cells are arranged, for example, in a staggered configuration. The memory cell to which the bit line BLj and the source line SLLi are connected will be denoted as the memory cell MCL, and the memory cell to which the bit line /BLj and the source line SLRi are connected will be denoted as the memory cell MCR.

The circuit configuration of the memory cell array 10 will be described using FIG. 13.

The memory cell MC includes a memory element 30 and a diode 46. One end of the memory element 30 is connected to the bit line and the other end thereof is connected to the anode of the diode 46. The cathode of the diode 46 is connected to the source line.

The bit lines BLj, /BLj are connected to the page buffer 11. One column of the memory cell array 10 is connected to one bit line.

The source lines SLLi, SLRi are connected to a source line driver (SL driver) 13. One row of the memory cell array 10 is connected to one source line. For the selection of the memory cell MC, a voltage equal to a built-in potential or more is applied to the diode 46.

Incidentally, the order of connection of the memory element 30 and the diode 46 may be reversed. In such a case, one end of the memory element 30 is connected to the source line and the other end is connected to the cathode of the diode 46. The anode of the diode 46 is connected to the bit line.

As the diode 46, a diode-connected transistor may be used.

Returning to FIG. 12, the memory cell array 10 includes a dummy source line pair, reference cells RCL, RCR, and pulldown circuits PDL, PDR.

The dummy source line pair (dummy source lines DSLL, DSLR) is included in a plurality of source lines. The dummy source line DSLL is connected to the reference cell RCL and the dummy source line DSLR is connected to the reference cell RCR. The dummy source line pair is arranged such that, for example, the plurality of source lines are sandwiched between the dummy source line pair and the page buffer 11.

The arrangement of the pulldown circuits PDL, PDR is the same as in the first embodiment.

The circuit configuration of the reference cell and the pulldown circuit PD will be described using FIG. 14. FIG. 14 is a circuit diagram of the memory cell array 10 and the page buffer 11 included in the semiconductor memory device 1 according to the second embodiment. FIG. 14 shows one memory cell MCL to which the source line SLLi is connected and one reference cell RCR.

The reference cell RCR includes a reference resistance element 32R (32) and a diode 47R (47). One end of the reference resistance element 32R is connected to the bit line /BLj and the other end thereof is connected to the anode of the diode 47R. The cathode of the diode 47R is connected to the dummy source line DSLR.

On the other hand, the reference cell RCL (not shown) includes a reference resistance element 32L (32) and a diode 47L (47). One end of the reference resistance element 32L is connected to the bit line BLj and the other end thereof is connected to the anode of the diode 47L. The cathode of the diode 47L is connected to the dummy source line DSLL.

Incidentally, the order of connection of the reference resistance element 32 and the diode 47 may be reversed. In such a case, one end of the reference resistance element 32 is connected to the source line SL and the other end is connected to the cathode of the diode 47. The anode of the diode 47 is connected to the bit line.

The pulldown circuit PDL includes a pulldown resistance element 34L (34) and a diode 48L (48). One end of the pulldown resistance element 34L is connected to the bit line BLj and the other end thereof is connected to the anode of the diode 48L. The cathode of the diode 48L is connected to a node DIO_L.

On the other hand, the pulldown circuit PDR includes a pulldown resistance element 34R (34) and a diode 48R (48). One end of the pulldown resistance element 34R is connected to the bit line /BLj and the other end thereof is connected to the anode of the diode 48R. The cathode of the diode 48R is connected to a node DIO_R.

Incidentally, the order of connection of the pulldown resistance element 34 and the diode 48 may be reversed. In such a case, one end of the pulldown resistance element 34 is connected to the node DIO_L or DIO_R and the other end is connected to the cathode of the diode 48. The anode of the diode 48 is connected to the bit line.

The circuit configuration of the page buffer 11 shown in FIG. 14 is the same as in the first embodiment.

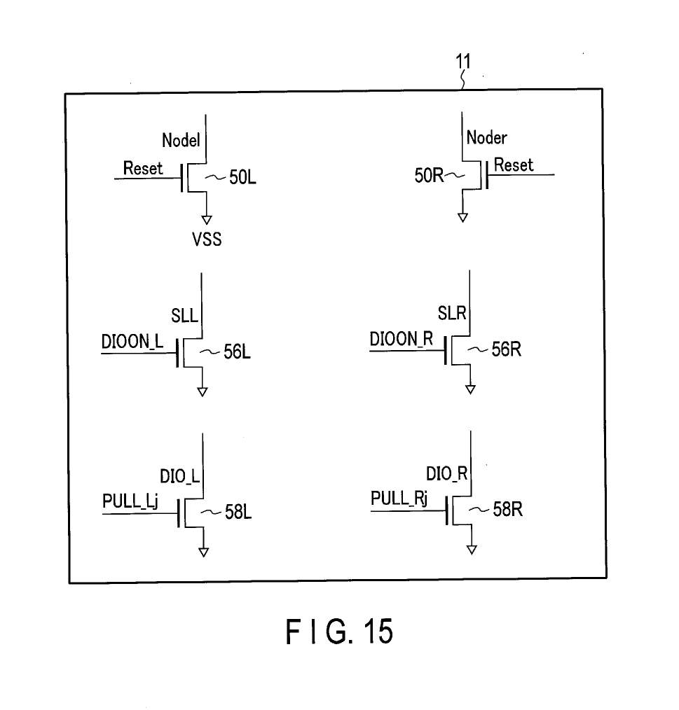

Another circuit configuration of the page buffer 11 will be described using FIG. 15.

The page buffer 11 includes transistors 56L, 56R.

The transistor 56L is an n-channel MOS transistor and one end thereof is connected to the source line SLLi, the ground voltage is applied to the other end, and a control signal DIOON_L is input into the gate thereof. The transistor 56R is an n-channel MOS transistor and one end thereof is connected to the source line SLRi, the ground voltage is applied to the other end, and the control signal DIOON_R is input into the gate thereof. When the transistors 56L, 56R are turned on during a read operation, a charge is pulled from the bit line toward the grounding terminal through the memory cell MC and the reference cell RC, and the voltage of the bit line nodes SA0, /SA0 drops.

The transistor 58L is an n-channel MOS transistor and one end thereof is connected to the node DIO_L, the ground voltage is applied to the other end, and a control signal PULL_Lj is input into the gate thereof. The transistor 58R is an n-channel MOS transistor and one end thereof is connected to the node DIO_R, the ground voltage is applied to the other end, and a control signal PULL_Rj is input into the gate thereof. When the transistors 56L, 56R are turned on during a pulldown operation, a charge is pulled from the bit line toward the grounding terminal through the pulldown resistance element 34 and the voltage of the bit line nodes SA0, /SA0 drops.

A circuit (not shown) that controls the voltage of dummy source lines DSLL, DSLR corresponding to the reference cells RCL, RCR has a configuration in which, for example, the source lines SLLi, SLRi and the dummy source lines DSLL, DSLR in a circuit controlling the voltage of the memory cells MCL, MCR are interchanged.

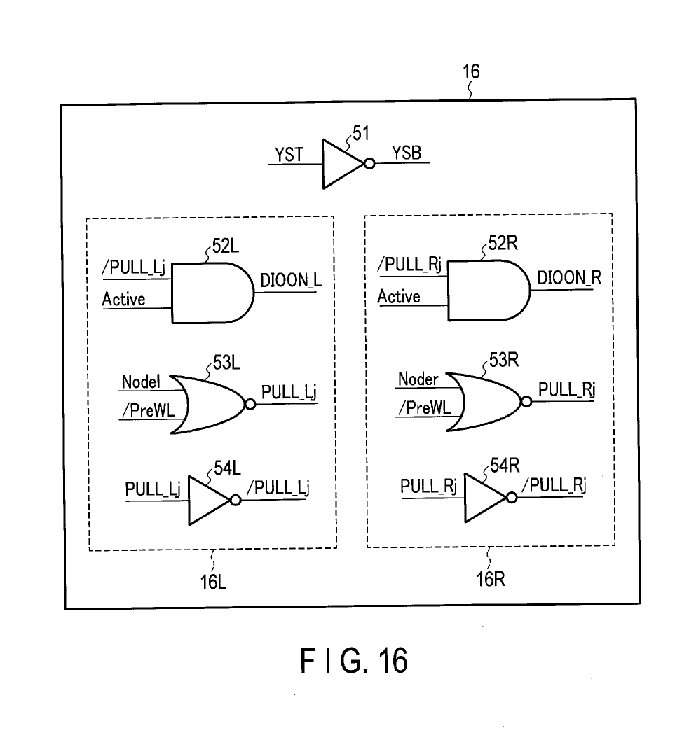

Only differences in the logic circuit configuration of a sequencer 16 related to the operation of the page buffer 11 from the logic circuit configuration thereof in FIG. 8 will be described using FIG. 16. FIG. 16 is a circuit diagram of the sequencer 16 included in the semiconductor memory device 1 according to the second embodiment.

An AND gate 52L performs an AND operation of a control signal /PULL_Lj and a control signal Active and outputs the control signal DIOON_L. An AND gate 52R performs an AND operation of a control signal /PULL_Rj and the control signal Active and outputs the control signal DIOON_R. When data of the memory cell MCL to which the source line SLLi is connected is read, the control signal DIOON_L is input into the gate of the transistor 56L, which causes the source line SLLi to drop to the ground voltage. At this point, the ground voltage is applied to the dummy source line DSLR. On the other hand, when data of the memory cell MCR to which the source line SLRi is connected is read, the control signal DIOON_R is input into the gate of the transistor 56R, which causes the source line SLRi to drop to the ground voltage. At this point, the ground voltage is applied to the dummy source line DSLL.

A NOR gate 53L performs a NOT-OR operation of the voltage of a node Nodel and a control signal /PreWL and outputs the control signal PULL_Lj. A NOR gate 53R performs a NOT-OR operation of the voltage of a node Noder and the control signal /PreWL and outputs the control signal PULL_Rj.

An inverter circuit 54L inverts the control signal PULL_Lj and outputs the control signal /PULL_Lj. An inverter circuit 54R inverts the control signal PULL_Rj and outputs the control signal /PULL_Rj.

The timing chart of the operation of the semiconductor memory device 1 according to the second embodiment is the same as a timing chart in which control signals GATEL, GATER in FIG. 9 are replaced by the control signals PULL_L, PULL_R and a control signal WL is replaced by the control signal Active. Hereinafter, only differences from the first embodiment will be described.

If the control signal DIOON_L changes to the “H” level, the transistor 56L is turned on and the ground voltage is applied to the source line SLLi. On the other hand, if the control signal DIOON_L changes to the “L” level, the transistor 56L is turned off and a current path between the source line SLLi and the grounding terminal is cut off.

Similarly, if the control signal DIOON_R changes to the “H” level, the transistor 56R is turned on and the ground voltage is applied to the source line SLRi. On the other hand, if the control signal DIOON_R changes to the “L” level, the current path between the source line SLRi and the grounding terminal is cut off.

If the control signal PULL_Lj changes to the “H” level, the transistor 58L is turned on and the ground voltage is applied to the node DIO_L. On the other hand, if the control signal PULL_Lj changes to the “L” level, the transistor 58L is turned off and the current path between the node DIO_L and the grounding terminal is cut off.

Similarly, if the control signal PULL_Rj changes to the “H” level, the transistor 58R is turned on and the ground voltage is applied to the node DIO_R. On the other hand, if the control signal PULL_Rj changes to the “L” level, the transistor 58R is turned off and the current path between the node DIO_R and the grounding terminal is cut off.

With the above configuration, the semiconductor memory device 1 according to the second embodiment can obtain the same effect as that in the first embodiment. Also, the semiconductor memory device 1 according to the second embodiment selects the memory cell MC by the source line, and also, when compared with the first embodiment, the area of the memory cell array 10 can be reduced because the area of the diode is less than that of the transistor.

### Third Embodiment

A semiconductor memory device 1 according to the third embodiment amplifies read data sensed by a transistor 37 by a current mirror circuit CM1 and latches the amplified read data by a data holding circuit DL.

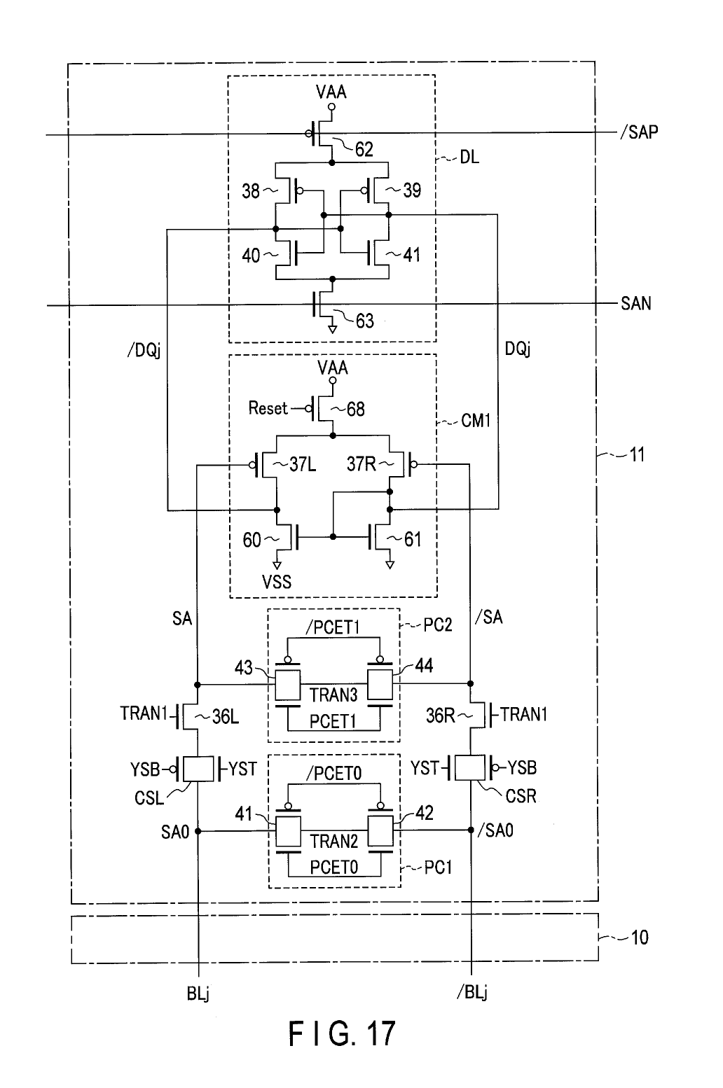

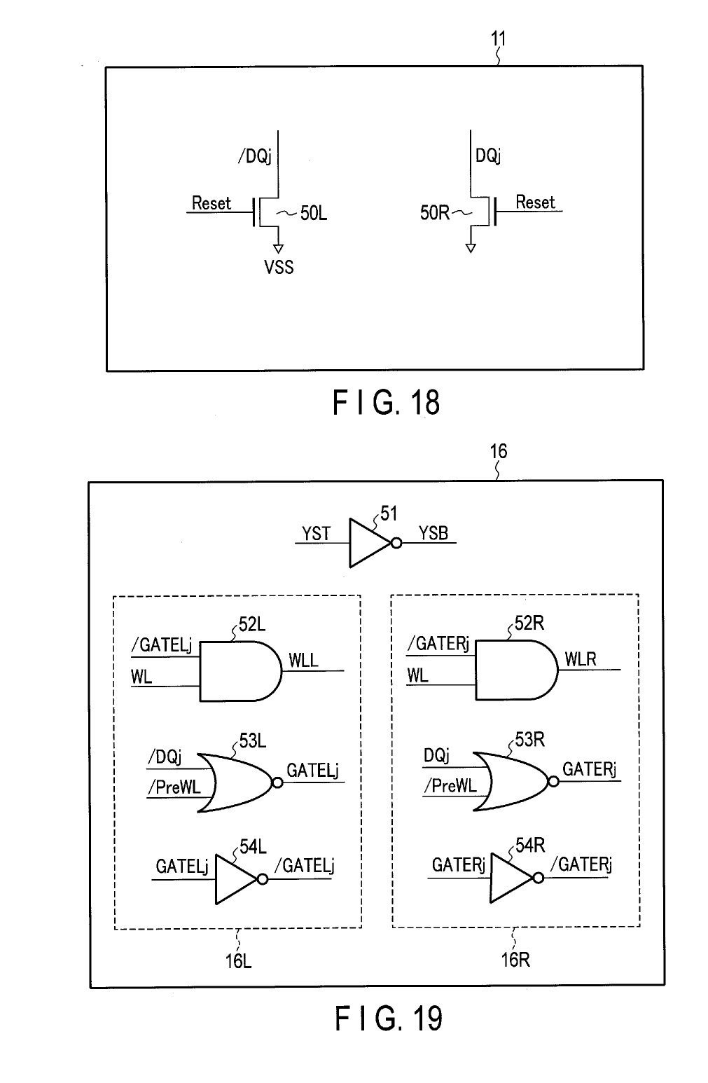

Only differences in the circuit configuration of a page buffer 11 from the circuit configuration thereof in the first embodiment will be described, using FIGS. 17 and 18. FIGS. 17 and 18 are circuit diagrams of the page buffer 11 included in the semiconductor memory device according to the third embodiment. A memory cell array 10 is configured in the same manner as in the first embodiment. Incidentally, the memory cell array 10 may be configured in the same manner as in the second embodiment.

As shown in FIG. 17, the page buffer 11 includes the current mirror circuit CM1. The current mirror circuit CM1 includes p-channel MOS transistors 37L, 37R, 68 and n-channel MOS transistors 60, 61.

One end of the transistor 37L is connected to one end of the transistor 68, the other end thereof is connected to a node /DQj, and the gate thereof is connected to a sense node SA. One end of the transistor 37R is connected to the one end of the transistor 68, the other end thereof is connected to a node DQj, and the gate thereof is connected to a sense node /SA. The power supply voltage VAA is applied to the other end of the transistor 68, the control signal Reset is input into the gate thereof.

One end of the transistor 60 is connected to the node /DQj, the ground voltage is applied to the other end thereof, and the gate thereof is connected to the gate of the transistor 61. One end and the gate of the transistor 61 are connected to the node DQj and the ground voltage is applied to the other end thereof.

With the above configuration, the current mirror circuit CM1 amplifies a potential difference between the sense nodes SA, /SA and outputs the amplified potential difference to the nodes DQj, /DQj to be able to latch data.

The data holding circuit DL further includes transistors 62, 63. The transistor 62 is a p-channel MOS transistor and the power supply voltage VAA is applied to one end thereof, the other end is connected to one ends of transistors 38, 39, and a control signal /SAP is input into the gate thereof. The transistor 63 is an n-channel MOS transistor and one end thereof is connected to the other ends of transistors 40, 41, the ground voltage is applied to the other end, and a control signal SAN is input into the gate thereof.

As shown in FIG. 18, one end of a transistor 50L is connected to the node /DQj and one end of a transistor 50R is connected to the node DQj.

Only differences of the logic circuit configuration of a sequencer 16 related to the operation of the page buffer 11 from the logic circuit configuration thereof in FIG. 8 will be described, using FIG. 19. FIG. 19 is a circuit diagram of the sequencer 16 included in the semiconductor memory device 1 according to the third embodiment.

A NOR gate 53L performs a NOT-OR operation of the voltage of the node /DQj and the control signal /PreWL and outputs the control signal GATELj. A NOR gate 53R performs a NOT-OR operation of the voltage of the node DQj and the control signal /PreWL and outputs the control signal GATERj.

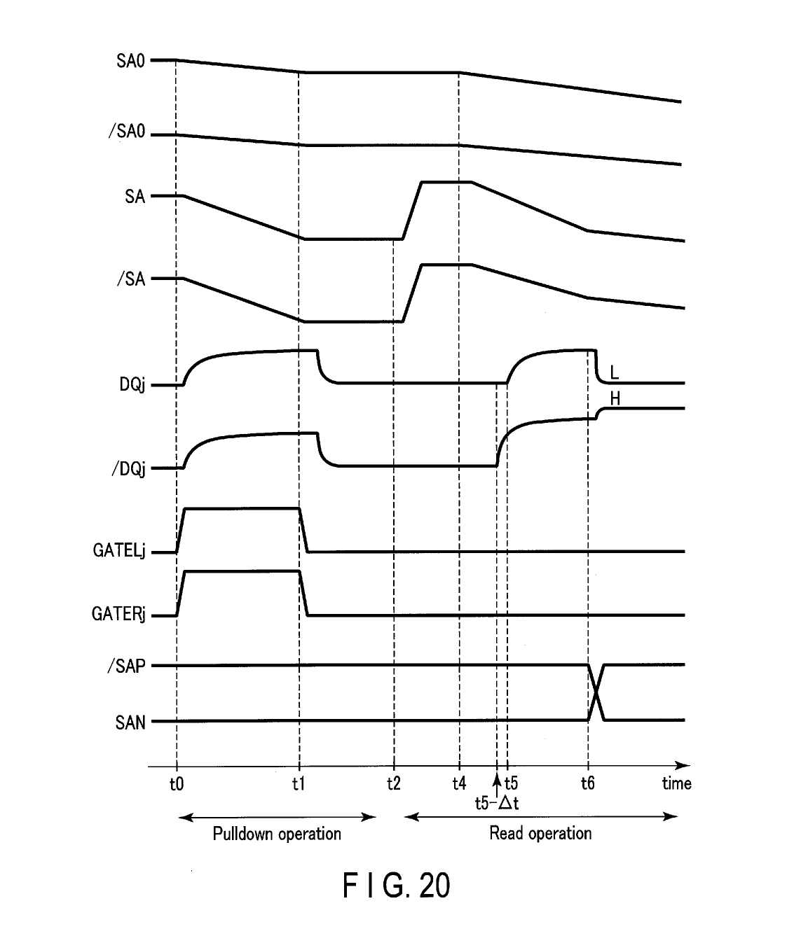

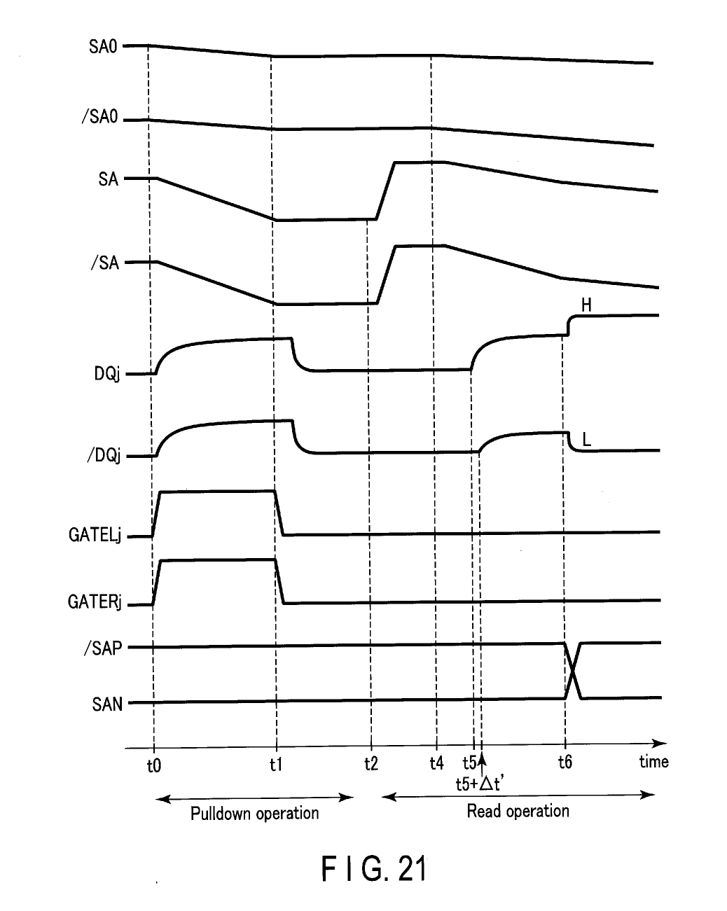

Only differences in the operation of the semiconductor memory device 1 according to the third from the operation thereof in the first embodiment will be described, using FIGS. 20 and 21. FIG. 20 is a timing chart when data of the memory cell MC to be read is “0” and FIG. 21 is a timing chart when data of the memory cell MC to be read is “1”. The times in FIGS. 20 and 21 correspond to the times in FIG. 9.

At time t0, if the control signals GATEL, GATER are set to the “H” level, the voltage of the sense nodes SA, /SA drops and the transistors 37L, 37R are turned on. Accordingly, the power supply voltage VAA is applied to the nodes /DQj, DQj and the voltage thereof rises.

At time t1, when the voltage of the nodes /DQj, DQj reaches the “H” level, the control signals GATEL, GATER change to the “L” level correspondingly. Then, the voltage of the nodes /DQj, DQj is discharged to change to the “L” level.

At time t5, t5−Δt or t5+Δt′, one of the transistors 37L, 37R is turned on in accordance with the speed of the voltage drop of the sense nodes SA, /SA.

If, as shown in FIG. 20, data of the memory cell MC to be read is “0”, the voltage of the sense node SA first drops and the transistor 37L is first turned on. As illustrated in FIG. 20, the time is t5−Δt. Accordingly, the power supply voltage VAA is applied to the node /DQj and amplified by the current mirror circuit CM1. The transistor 37R is also turned on a little later and the voltage of the node DQj starts to rise. Accompanying the operation of the current mirror circuit CM1, the potential difference between the nodes /DQj, DQj is amplified.

During the period when the potential difference between the nodes /DQj, DQj becomes wide enough, the control signal /SAP is changed from the “H” level to the “L” level and the control signal SAN is changed from the “L” level to the “H” level (time t6). Accordingly, the node /DQj changes to the “H” level and “0” data is held in the data holding circuit DL.

On the other hand, if, as shown in FIG. 21, data of the memory cell MC to be read is “1”, the voltage of the sense node /SA first drops and the transistor 37R is first turned on. Accordingly, the power supply voltage VAA is applied to the node DQj. Accompanying the operation of the current mirror circuit CM1, the potential difference between the nodes /DQj, DQj is amplified.

During the period when the potential difference between the nodes /DQj, DQj becomes wide enough, the control signal /SAP is changed from the “H” level to the “L” level and the control signal SAN is changed from the “L” level to the “H” level (time t6). Accordingly, the node DQj changes to the “H” level and “1” data is held in the data holding circuit DL.

Time t6 is a parameter determined in advance by a simulation or the like and is set with a sufficient interval such that erroneous reading should not occur.

With the above configuration, the semiconductor memory device 1 according to the third embodiment can obtain the same effect as that in the first embodiment.

### Fourth Embodiment

A semiconductor memory device 1 according to the fourth embodiment is, compared with the semiconductor memory device 1 in the third embodiment, further provided with a current mirror circuit CM2 to amplify a node DQj.

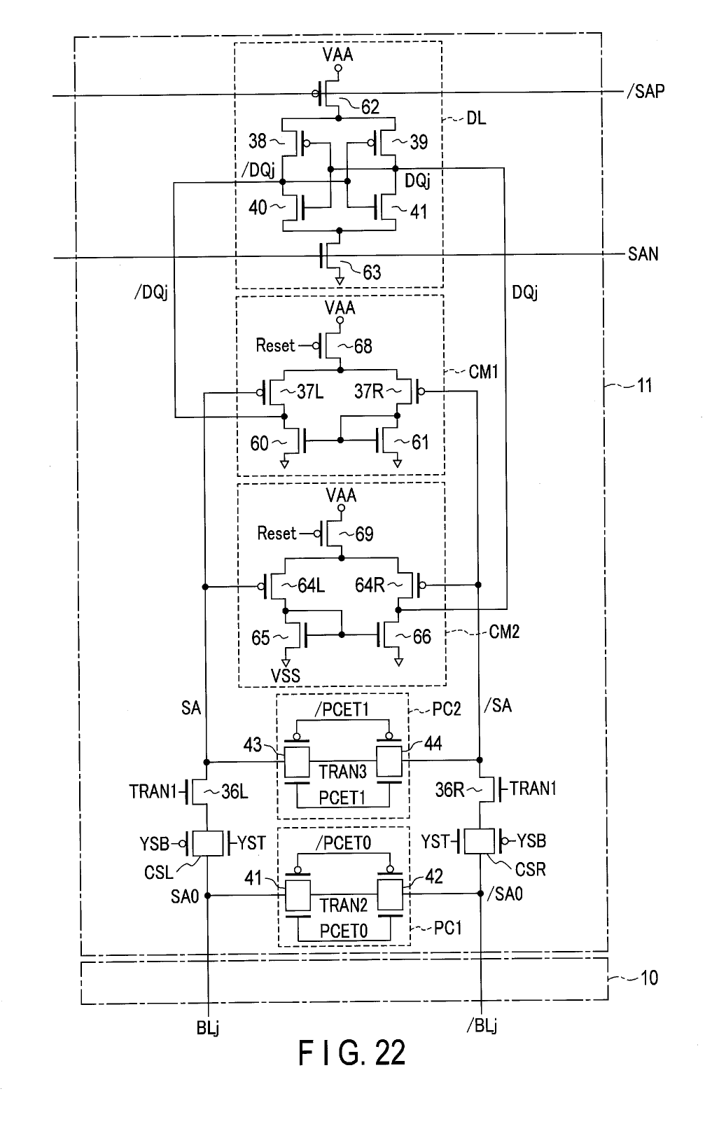

Only differences in the circuit configuration of a page buffer 11 from the circuit configuration thereof in the third embodiment will be described, using FIG. 22. FIG. 22 is a circuit diagram of the page buffer 11 included in a semiconductor memory device 1 according to the fourth embodiment. The page buffer 11 includes the current mirror circuit CM2.

The current mirror circuit CM2 includes p-channel MOS transistors 64L, 64R and n-channel MOS transistors 65, 66.

One end of the transistor 64L is connected to one end of the transistor 69, the other end thereof is connected to one end of the transistor 65, and the gate thereof is connected to a sense node SA. One end of the transistor 64R is connected to the one end of the transistor 69, the other end thereof is connected to one end of the transistor 66, and the gate thereof is connected to a sense node /SA. The power supply voltage VAA is applied to the other end of the transistor 69, the control signal Reset is input into the gate thereof. The gate of the transistor 65 is connected to the gate of the transistor 66 and the one end of the transistor 64L, and the ground voltage is applied to the other end thereof. One end of the transistor 66 is connected to a node DQj, and the ground voltage is applied to the other end thereof.

A node /DQj is connected to one end of a transistor 37L and the node DQj is connected to one end of the transistor 64R.

With the above configuration, a current mirror circuit CM1 output the voltage of the node /DQj by amplifying a difference between a voltage of the sense node /SA and a voltage of the sense node SA, a current mirror circuit CM2 output a voltage of the node DQj by amplifying a difference between the voltage of the sense node SA and the voltage of the sense node /SA.

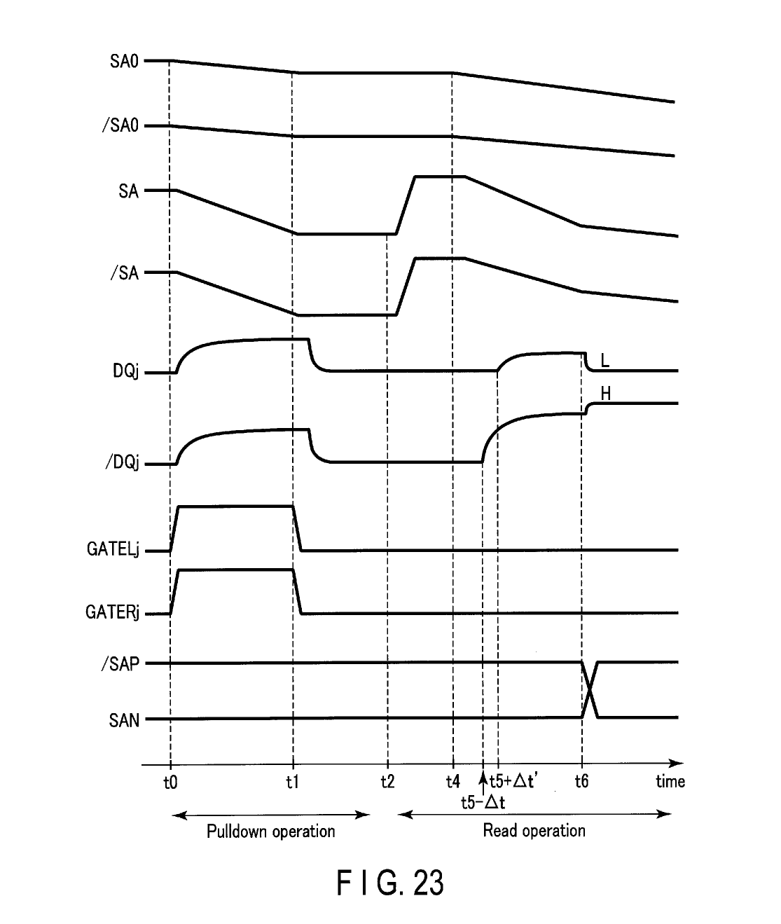

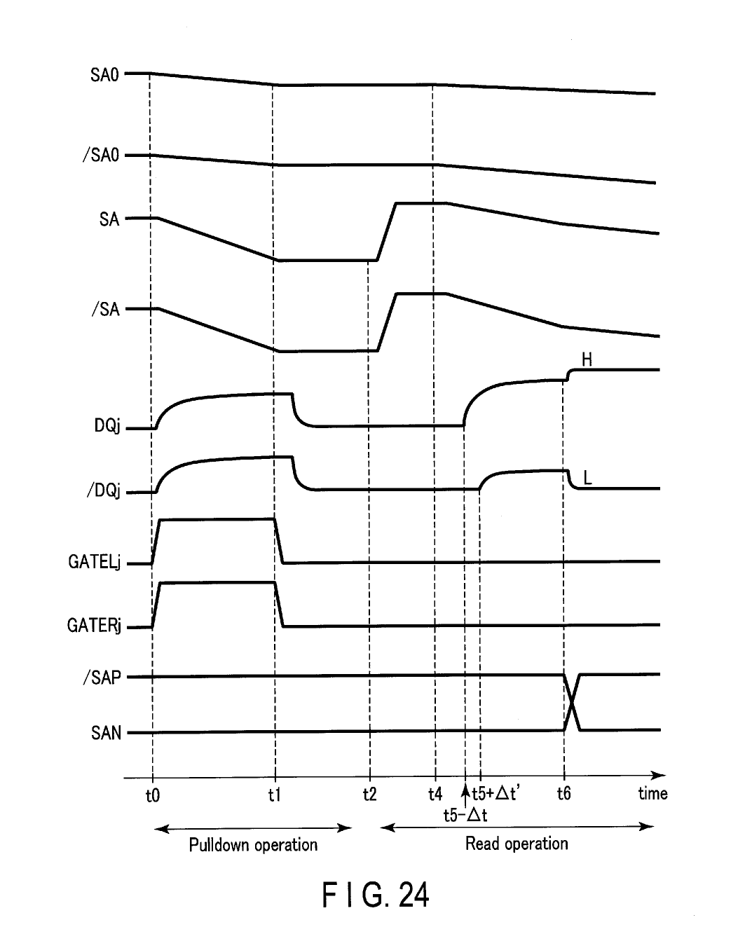

Only differences of the operation of the semiconductor memory device 1 according to the fourth from the operation thereof in the third embodiment will be described using FIGS. 23 and 24. FIG. 23 is a timing chart when data of the memory cell MC to be read is “0” and FIG. 24 is a timing chart when data of the memory cell MC to be read is “1”. The times in FIGS. 23 and 24 correspond to the times in FIGS. 20 and 21 respectively.

The case when data of the memory cell MC to be read is “0” and the case when data of the memory cell MC to be read is “1” are different in the voltage values and timing to which nodes /DQ, DQ are charged after time t5.

At time t5−Δt or t5+Δt′, one of the transistors 37L, 64R is turned on in accordance with the speed of the voltage drop of the sense nodes SA, /SA.

If data of the memory cell MC to be read is “0”, the voltage of the node /DQj is amplified by the current mirror circuit CM1 and if data of the memory cell MC to be read is “1”, the voltage of the node DQj is amplified by the current mirror circuit CM2. Accordingly, in both cases of reading “0” data and “1” data, the voltage difference of the nodes /DQj, DQj can be increased.

With the above configuration, the semiconductor memory device 1 according to the fourth embodiment can obtain the same effect as that in the first embodiment and the probability of erroneously reading data can be reduced when compared with the third embodiment.

### Fifth Embodiment

In a semiconductor memory device 1 according to the fifth embodiment, a sense node is directly connected to a data holding circuit DL.

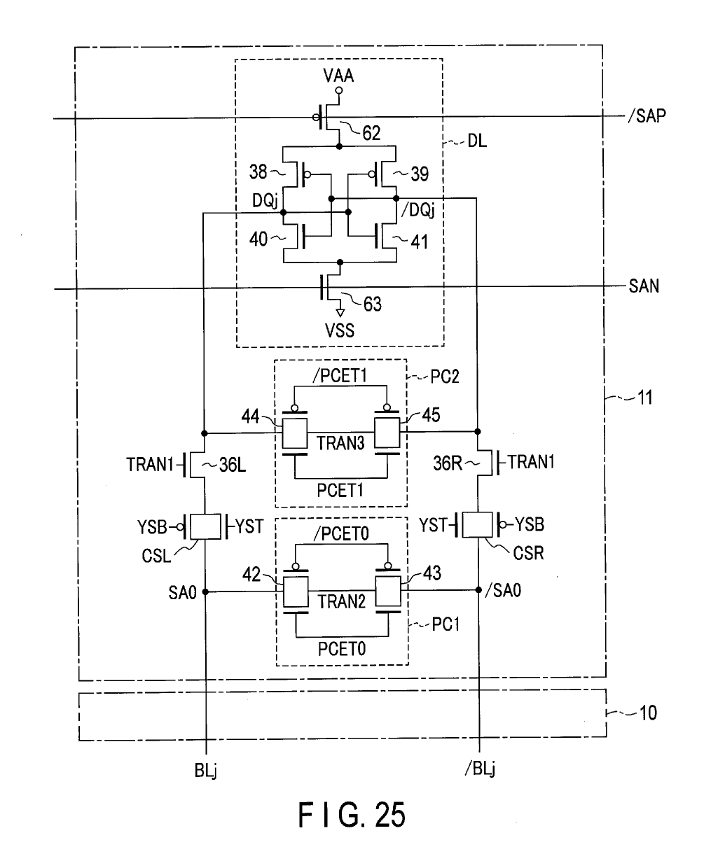

Only differences in the circuit configuration of a page buffer 11 from the circuit configuration thereof in the third embodiment will be described, using FIG. 25. FIG. 25 is a circuit diagram of the page buffer 11 included in the semiconductor memory device 1 according to the fifth embodiment.

One end of a charge transfer transistor 36L is connected to a node DQj and one end of a charge transfer transistor 36R is connected to a node /DQj. That is, when compared with the third and fourth embodiments, the correspondence of the nodes /DQj, DQj of the data holding circuit DL is reversed.

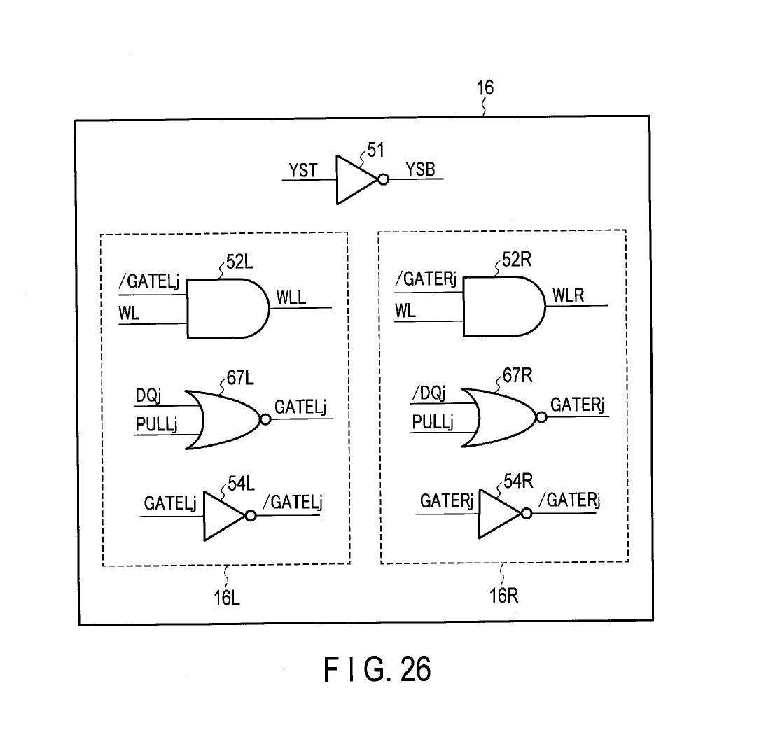

Only differences of the logic circuit configuration of a sequencer 16 related to the operation of the page buffer 11 from the logic circuit configuration thereof in FIG. 8 will be described, using FIG. 26. FIG. 26 is a circuit diagram of the sequencer 16 included in the semiconductor memory device 1 according to the fifth embodiment.

Control circuits 16L, 16R include NOR gates 67L, 67R respectively.

The NOR gate 67L performs an NOT-OR operation of the voltage of the node DQj and the control signal PULLj and outputs the control signal GATELj. The NOR gate 67R performs an NOT-OR operation of the voltage of the node /DQj and the control signal PULLj and outputs the control signal GATERj. The control signal PULLj controls the pulldown operation described later.

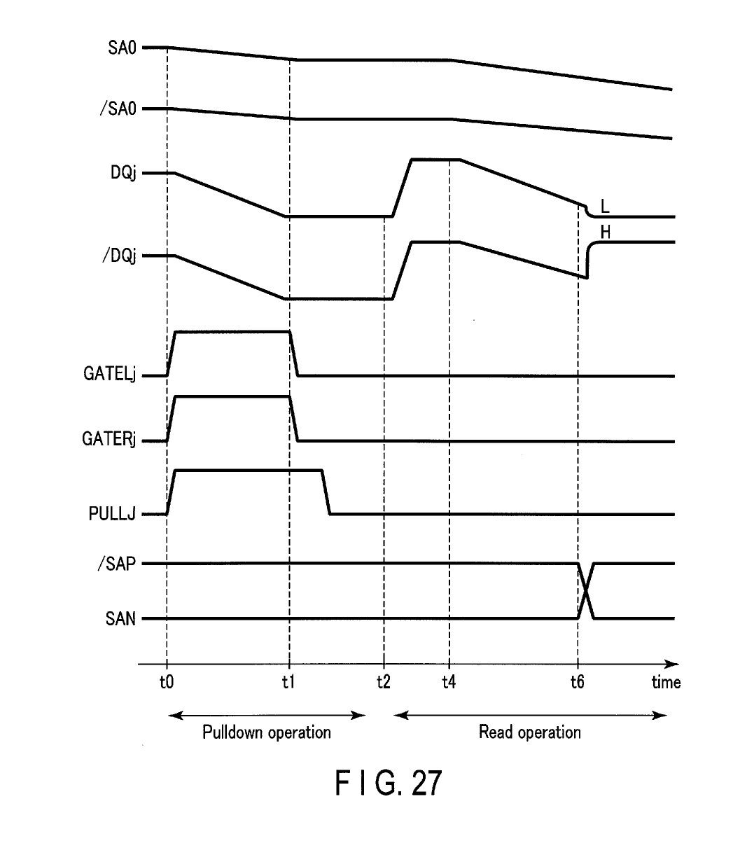

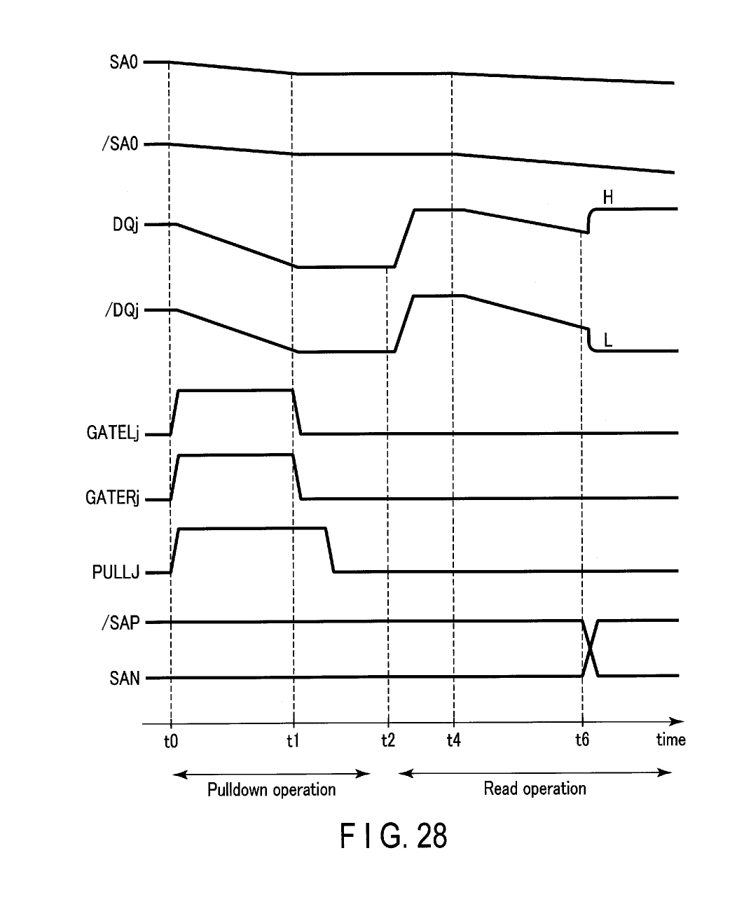

Only differences in the operation of the semiconductor memory device 1 according to the fifth from the operation thereof in the first embodiment will be described, using FIGS. 27 and 28. FIG. 27 is a timing chart when data of the memory cell MC to be read is “0” and FIG. 28 is a timing chart when data of the memory cell MC to be read is “1”. The times in FIGS. 27 and 28 correspond to the times in FIGS. 20 and 21 respectively.

If, at time t0, the control signal PULLj changes to the “H” level, a pulldown operation is started. The control signal PULLj is set to the “L” level after time t1. The period in which the control signal PULLj is at the “H” level (the period in which the pulldown operation is performed) is determined in advance by a simulation or the like.

The operations of the nodes DQj, /DQj up to time t4 correspond to those of sense nodes SA, /SA in the first embodiment respectively. At time t4, the control signal WL is set to the “H” level to start a read operation, and the voltage of the nodes DQj, /DQj starts to drop.

If, as shown in FIG. 27, data of the memory cell MC to be read is “0”, the speed of the voltage drop of the node DQj is faster than the speed of the voltage drop of the node /DQj. Accordingly, a voltage difference between the nodes DQj, /DQj arises at time t6 and the voltage of the node /DQj becomes higher than the voltage of the node DQj. At this point, when the control signal /SAP is changed from the “H” level to the “L” level and the control signal SAN is changed from the “L” level to the “H” level, the node /DQj is set to the “H” level and “0” data is held in the data holding circuit DL.

If, as shown in FIG. 28, data of the memory cell MC to be read is “1”, the speed of the voltage drop of the node DQj is slower than the speed of the voltage drop of the node /DQj. Accordingly, a voltage difference between the nodes DQj, /DQj arises at time t6 and the voltage of the node DQj becomes higher than the voltage of the node /DQj. At this point, when the control signal /SAP is changed from the “H” level to the “L” level and the control signal SAN is changed from the “L” level to the “H” level, the node DQj is set to the “H” level and “1” data is held in the data holding circuit DL.

With the above configuration, the semiconductor memory device 1 according to the fifth embodiment can obtain the same effect as that in the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a plurality of memory cells, each of which including a memory element and a first switch element, the memory element storing data in accordance with a resistance values; a bit line connected to the memory cells;
a charge transfer transistor that connects the bit line and a sense node;
a sense circuit connected to the sense node; and
a pulldown circuit connected to the bit line, wherein
the pulldown circuit causes a voltage of the bit line to drop to a first voltage obtained by subtracting a threshold voltage of the charge transfer transistor from a gate voltage of the charge transfer transistor before reading the data from the memory cell.

2. The device of claim 1, wherein
the pulldown circuit includes a resistance element and a second switch element,
a first terminal of the resistance element is connected to the bit line;
a second terminal of the resistance element is connected to a first terminal of the second switch element, and
a second terminal of the second switch element is connected to a grounding terminal.

3. The device of claim 1, wherein
the sense circuit includes a first PMOS transistor and a latch circuit,
the first PMOS transistor is connected between a power supply terminal and the latch circuit, and
a gate of the first PMOS transistor is connected to the sense node.

4. The device of claim 1, further comprising:
a word line, wherein
the first switch element is configured by a select transistor and
a gate of the select transistor is connected to the word line.

5. The device of claim 1, wherein
the first switch element is configured by a diode.

6. The device of claim 2, wherein
a resistance value of the resistance element is approximately equal to a reference resistance value to determine a high-resistance state and a low-resistance state of the memory element.

7. The device of claim 2, wherein
a resistance value of the resistance element is approximately equal to a value of a high-resistance state of the memory element.

8. The device of claim 2, wherein
a resistance value of the resistance element is approximately equal to a value of a low-resistance state of the memory element.

9. The device of claim 1, further comprising:
a controller that turns on the first switch element after the bit line drops to the first voltage, wherein
the pulldown circuit stops an operation of the pulldown circuit after the voltage of the bit line drops to the first voltage.

10. The device of claim 2, further comprising:
a controller, wherein
the sense circuit includes a first PMOS transistor and a latch circuit,
the first PMOS transistor is connected between a power supply terminal and the latch circuit,
a gate of the first PMOS transistor is connected to the sense node, and
the controller turns off the second switch element in accordance with a change in a voltage of a drain of the first PMOS transistor from a low level to a high level before reading the data from the memory cell.

11. The device of claim 2, further comprising:
a controller that inputs an AND of an inverted signal of a signal input into the second switch element and an active signal to read the data from the memory cell into the first switch element.

12. The device of claim 3, wherein
the latch circuit includes first and second nodes that hold complementary data, and
the sense circuit includes a first current mirror circuit that output a voltage of the first node by amplifying a difference between a first voltage of the sense node and a second voltage of a complementary sense node to the sense node.

13. The device of claim 12, wherein
the sense circuit includes a second current mirror circuit that output a voltage of the second node by amplifying a difference between the first voltage and the second voltage.

14. The device of claim 12, wherein
the sense circuit includes a second PMOS transistor and an NMOS transistor,
the second PMOS transistor is connected between a power supply terminal and the first node or the second node, and
the NMOS transistor is connected between a grounding terminal and the first node or the second node.

15. The device of claim 1, wherein
the sense circuit includes a latch circuit, a PMOS transistor, and an NMOS transistor,
the latch circuit includes first and second nodes that hold complementary data,
the first node is connected to the sense node,
the PMOS transistor is connected between a power supply terminal and the latch circuit, and
the NMOS transistor is connected between a grounding terminal and the latch circuit.

16. The device of claim 15, further comprising:
a controller that controls the PMOS transistor and the NMOS transistor in accordance with a potential difference of the first node and the second node.

17. The device of claim 1, wherein
the pulldown circuit and the sense circuit are arranged to sandwich the memory cells therebetween.

18. The device of claim 1, wherein
the pulldown circuit is arranged between the memory cells.

19. The device of claim 1, further comprising:
a memory cell array being a set of the memory cells,
wherein the pulldown circuit is arranged at an end portion or in a center portion of the memory cell array.

20. The device of claim 1, wherein
the memory cell is one of an iPCM, PRAM, ReRAM, MRAM, and FeNAND.
